(19) United States
(12) Patent Application Publication
(10) Pub. No.: US 2025/0076388 A1
(43) Pub. Date: Mar. 6, 2025

(54) APPARATUS AND METHOD FOR DIAGNOSING BATTERY

(71) Applicant: LG ENERGY SOLUTION, LTD., Seoul (KR)

(72) Inventor: Soon-Hyung CHOI, Daejeon (KR)

(21) Appl. No.: 18/817,149

(22) Filed: Aug. 27, 2024

(30) Foreign Application Priority Data
Aug. 31, 2023 (KR) 10-2023-0115856

(51) Int. Cl. G01R 31/367; G01R 31/3835

(52) U.S. Cl. CPC G01R 31/367; G01R 31/3835

(57) ABSTRACT

An apparatus for diagnosing a battery according to one aspect of the present disclosure may include a profile obtaining unit configured to obtain each of a plurality of battery profiles indicating a correspondence relationship between voltage and capacity of each of a plurality of batteries; a profile correcting unit configured to generate a plurality of corrected profiles by correcting the plurality of battery profiles based on a preset overpotential profile, and generate an adjusted positive electrode profile and an adjusted negative electrode profile corresponding to each battery by adjusting a preset reference positive electrode profile and a preset reference negative electrode profile to correspond to each of the plurality of corrected profiles; and a control unit configured to extract a diagnostic factor for each battery from at least one of the adjusted positive electrode profile and the adjusted negative electrode profile, and diagnose the state of the plurality of batteries.

### CROSS-REFERENCE TO RELATED APPLICATIONS

The present application claims priority to Korean Patent Application No. 10-2023-0115856 filed on Aug. 31, 2023 in the Republic of Korea, the disclosure of which is hereby incorporated herein by reference in its entirety.

### TECHNICAL FIELD

Aspects of the present disclosure relate to an apparatus and method for diagnosing a battery, and more particularly, to an apparatus and method capable of diagnosing a state of a battery in consideration of overpotential.

### BACKGROUND

Recently, the demand for portable electronic products such as notebook computers, video cameras and portable telephones has increased sharply, and electric vehicles, energy storage batteries, robots, satellites and the like have been developed in earnest. Accordingly, high-performance batteries allowing repeated charging and discharging are being actively studied.

Batteries commercially available at present include nickel-cadmium batteries, nickel hydrogen batteries, nickel-zinc batteries, lithium batteries and the like. Among them, the lithium batteries are in the limelight since they have almost no memory effect compared to nickel-based batteries and also have very low self-charging rate and high energy density.

A lot of research is being conducted on these batteries in terms of high-capacity and high-density, but the aspect of improving lifespan and safety is also important. In order to improve the safety of the battery, technology to accurately diagnose the current state of the battery is required.

Conventionally, the state of the battery is diagnosed by analyzing the battery profile, which represents the correspondence relationship between capacity and voltage of the battery. For example, during the battery charging process, capacity and voltage are measured, and the battery state is diagnosed through analysis of the battery profile, which represents the correspondence relationship between the measured capacity and voltage. As another example, the state of the battery may be diagnosed based on the capacity and voltage measured during the battery discharge process.

Here, in order to more accurately diagnose the current state of the battery, a battery profile that accurately reflects the current state of the battery is required. However, in order to obtain this battery profile, there is a problem that low rate charging and discharging such as 0.05 C (C-rate) is required. That is, in the past, low-rate charging and discharging is required to diagnose the state of the battery, so there are limitations in diagnosing the state of the battery.

For example, when charging and discharging the battery at 0.3 C or above, the obtained battery profile includes overpotential, so the battery profile may not accurately reflect the current state of the battery due to the influence of overpotential. When using a battery profile that includes overpotential, there is concern that the state of the battery may not be accurately diagnosed, so low-rate charging and discharging is required to accurately diagnose the battery state.

The background description provided herein is for the purpose of generally presenting context of the disclosure. Unless otherwise indicated herein, the materials described in this section are not prior art to the claims in this application and are not admitted to be prior art, or suggestions of the prior art, by inclusion in this section

### DISCLOSURE

Aspects of the present disclosure are designed to solve the problems of the related art, and therefore aspects of the present disclosure are directed to providing an apparatus and method for diagnosing a battery in consideration of overpotential.

These and other objects and advantages of the present disclosure may be understood from the following detailed description and will become more fully apparent from the exemplary embodiments of the present disclosure. Also, it will be easily understood that the objects and advantages of the present disclosure may be realized by the means shown in the appended claims and combinations thereof.

An apparatus for diagnosing a battery according to one aspect of the present disclosure may comprise a profile obtaining unit configured to obtain each of a plurality of battery profiles indicating a correspondence relationship between voltage and capacity of each of a plurality of batteries; a profile correcting unit configured to generate a plurality of corrected profiles by correcting the plurality of battery profiles based on a preset overpotential profile, and generate an adjusted positive electrode profile and an adjusted negative electrode profile corresponding to each battery by adjusting a preset reference profile of the positive electrode and a preset reference profile of the negative electrode to correspond to each of the plurality of corrected profiles; and a control unit configured to extract a diagnostic factor for each battery from at least one of the adjusted positive electrode profile and the adjusted negative electrode profile, and diagnose the state of the plurality of batteries based on the extracted plurality of diagnostic factors.

The overpotential profile may be a profile that represents a voltage difference per capacity between a battery profile of a reference battery for a reference C-rate and the battery profile of the reference battery for a target C-rate set for the plurality of batteries.

The profile correcting unit may be configured to generate the plurality of corrected profiles by calculating a voltage difference per capacity between each of the plurality of battery profiles and the overpotential profile.

The overpotential profile may be configured to be stored in advance for each of the plurality of C-rates.

The profile correcting unit may be configured to select an overpotential profile corresponding to the target C-rate among the pre-stored plurality of overpotential profiles and generate the plurality of corrected profiles using the selected overpotential profile.

The control unit may be configured to select a diagnostic factor that is outside a threshold range among the plurality of diagnostic factors in consideration of the distribution of the plurality of diagnostic factors, and diagnose the state of a battery corresponding to the selected diagnostic factor as an abnormal state.

The control unit may be configured to extract at least one of a positive electrode factor based on the adjusted positive electrode profile, a negative electrode factor based on the adjusted negative electrode profile, and a positive and negative electrode factor based on the positive electrode factor and the negative electrode factor.

The positive electrode factor may be configured to include at least one of a positive electrode start potential, a positive electrode end potential, a positive electrode change rate, and a positive electrode loading amount of the battery based on the adjusted positive electrode profile.

The negative electrode factor may be configured to include at least one of a negative electrode start potential, a negative electrode end potential, a negative electrode change rate, and a negative electrode loading amount of the battery based on the adjusted negative electrode profile.

The positive and negative electrode may be is configured to include an NP ratio based on the positive electrode loading amount and the negative electrode loading amount. The profile correcting unit may be configured to generate a comparison full-cell profile based on the reference profile of the positive electrode and the reference profile of the negative electrode, and generate the adjusted positive electrode profile and the adjusted negative electrode profile by adjusting the reference profile of the positive electrode and the reference profile of the negative electrode until the generated comparison full-cell profile corresponds to the corrected profile.

A battery pack according to another aspect of the present disclosure may comprise the apparatus for diagnosing a battery according to the present disclosure.

A battery manufacturing system according to still another aspect of the present disclosure may comprise the apparatus for diagnosing a battery according to the present disclosure.

A vehicle according to still another aspect of the present disclosure may comprise the apparatus for diagnosing a battery according to the present disclosure.

A method for diagnosing a battery according to another aspect of the present disclosure may comprise a profile obtaining step of obtaining each of a plurality of battery profiles indicating a correspondence relationship between voltage and capacity of each of a plurality of batteries; a corrected profile generating step of generating a plurality of corrected profiles by correcting the plurality of battery profiles based on a preset overpotential profile; a profile adjusting step of generating an adjusted positive electrode profile and an adjusted negative electrode profile corresponding to each battery by adjusting a preset reference profile of the positive electrode and a preset reference profile of the negative electrode to correspond to each of the plurality of corrected profiles; a diagnostic factor extracting step of extracting a diagnostic factor for each battery from at least one of the adjusted positive electrode profile and the adjusted negative electrode profile; and a state diagnosing step of diagnosing the state of the plurality of batteries based on the extracted plurality of diagnostic factors.

According to one aspect, an apparatus for diagnosing a battery is provided. The apparatus may include a profile obtaining unit, a profile correcting unit, and a control unit. The profile obtaining unit may be configured to obtain a first profile, the first profile being based on a voltage value of the battery and a capacity value of the battery. The profile correcting unit configured to generate a second profile based on an overpotential profile associated with the first profile, and generate a third profile based on a first reference profile and the second profile. The control unit may be configured to generate one or more diagnostic factors based on the third profile, and determine a state of the battery based on the one or more diagnostic factors.

Any of the apparatus described herein may include any of the following features. The profile correcting unit may be further configured to generate a fourth profile based on a second reference profile and the second profile, and the control unit may be further configured to generate the one or more diagnostic factors based on the third profile or the fourth profile. The third profile may be an adjusted positive electrode profile, and the first reference profile may be a positive electrode reference profile. The overpotential profile may be generated based on a fifth profile and a sixth profile, the fifth profile may be based on a reference battery and the sixth profile being based on a target battery, and the fifth profile may be generated based on a first C-rate value and the sixth battery profile is generated based on a second C-rate value. The first C-rate value may be used for charging or discharge the reference battery, and the second C-rate value may be used for charging or discharging the target battery. The overpotential profile may be generated further based on a difference between a voltage value of the fifth profile and a voltage value of the sixth profile. The profile correcting unit may be further configured to generate the second profile by calculating a difference between a voltage value of the first profiles and a voltage value of the overpotential profile. A plurality of overpotential profiles corresponding to a plurality of C-rates may be obtained by the profile obtaining unit, the profile correcting unit may be further configured to select at least one of the plurality of overpotential profiles corresponding to the second C-rate, and the profile correcting unit may be further configured to generate second profiles based on the at least one of the plurality of overpotential profiles. The control unit may be further configured to select at least one of the one or more diagnostic factors, determine distribution data based on plurality of diagnostic factors, and determine the state of the battery based on the distribution data, wherein the state of the battery may be a first state or a second state. The first state may be outside of a threshold range of the distribution data, and the first state may be an abnormal state of the battery. The control unit may be further configured to determine at least one of a first factor based on the third profile, a second factor based on the fourth profile, or a third factor based on the first factor and the second factor. The first factor may be based on at least one of a first electrode start potential, a first electrode end potential, a first electrode change rate, or a first electrode loading amount of the battery, and at least one of the first electrode start potential, the first electrode end potential, the first electrode change rate, or the first electrode loading amount of the battery may be based on the third profile. The second electrode factor may be based on the at least one of a second electrode start potential, a second electrode end potential, a second electrode change rate, or a second electrode loading amount of the battery, the at least one of the second electrode start potential, the second electrode end potential, the second electrode change rate, or the second electrode loading amount of the battery may be based on the fourth profile, and the third electrode factor is based on a ratio between the first electrode loading amount and the second electrode loading amount. The profile correcting unit may be further configured to generate a comparison profile based on the first reference profile and the second reference profile, and generate the third profile and the fourth profile by adjusting the first reference profile and the second reference profile, and the first reference profile and the second reference profile may be adjusted to generate the comparison profile that corresponds with the second profile.

According to one aspect, a battery pack may be provided. The battery pack may include the apparatus for diagnosing the battery described in the foregoing disclosure.

According to one aspect, a battery manufacturing system may be provided. The battery manufacturing system may include the apparatus for diagnosing the battery described in the foregoing disclosure.

According to one aspect, vehicle may be provided. The vehicle may include the apparatus for diagnosing the battery described in the foregoing disclosure.

According to one aspect, a method is provided for diagnosing a battery. The method may include: obtaining a first profile, the first profile being based on a voltage value of the battery and a capacity value of the battery; generating a second profile based on an overpotential profile associated with the first profile; generating a third profile based on a first reference profile and the second profile; generating one or more diagnostic factors based on the third profile; and determining a state of the battery based on the one or more diagnostic factors.

Any of the methods described here may include any of the following steps or features. The method may further include generating a fourth profile based on a second reference profile and the second profile, and generating the diagnostic factor based on the third profile or the fourth profile. The third profile may be a positive electrode profile, and the first reference profile may be a positive electrode reference profile. The method may further include generating the overpotential profile based on a fifth profile and a sixth profile, the fifth profile and the sixth profile being based on a reference battery, generating the fifth profile based on a first C-rate value, and generating the sixth battery profile based on a second C-rate value.

The apparatus for diagnosing a battery according to the present disclosure diagnoses the state of the battery based on a corrected profile in which the overpotential is removed from the battery profile, so charging and discharging at the reference C-rate is not forced to diagnose the state of the battery. In other words, since the state of the battery can be diagnosed even if the battery is charged and discharged at a C-rate other than the reference C-rate, the state of the battery can be diagnosed quickly without restrictions on charging and discharging conditions.

In addition, the apparatus for diagnosing a battery has an advantage of quickly distinguishing a normal battery and an abnormal battery by relatively comparing the states of the plurality of batteries based on the distribution of the plurality of diagnostic factors. The effects of the present disclosure are not limited to the effects mentioned above, and other effects not mentioned will be clearly understood by those skilled in the art from the description of the claims.

### BRIEF DESCRIPTION OF DRAWINGS

The accompanying drawings illustrate a preferred embodiment of the present disclosure and together with the foregoing disclosure, serve to provide further understanding of the technical features of the present disclosure, and thus, the present disclosure is not construed as being limited to the drawing.

FIG. 1 is a diagram schematically showing an apparatus for diagnosing a battery according to an embodiment of the present disclosure.

FIG. 2 is a diagram schematically showing an overpotential profile according to an embodiment of the present disclosure.

FIG. 3 is a diagram schematically showing a battery profile according to an embodiment of the present disclosure.

FIG. 4 is a diagram schematically showing a corrected profile according to an embodiment of the present disclosure.

FIG. 5 is a diagram schematically showing the distribution of diagnostic factors according to an embodiment of the present disclosure.

FIGS. 6 to 14 are diagrams showing the distribution of diagnostic factors according to an embodiment of the present disclosure.

FIGS. 15 to 22 are diagrams for explaining the process of adjusting a reference profile of the positive electrode and a reference profile of the negative electrode according to an embodiment of the present disclosure.

FIG. 23 is a diagram schematically showing an exemplary configuration of a battery pack according to another embodiment of the present disclosure.

FIG. 24 is a diagram for explaining the process of manufacturing a battery cell by a battery manufacturing system according to still another embodiment of the present disclosure.

FIG. 25 is a diagram schematically showing an exemplary configuration of a vehicle according to still another embodiment of the present disclosure.

FIG. 26 is a diagram schematically showing a method for diagnosing a battery according to still another embodiment of the present disclosure.

### DETAILED DESCRIPTION

It should be understood that the terms used in the specification and the appended claims should not be construed as limited to general and dictionary meanings, but interpreted based on the meanings and concepts corresponding to technical aspects of the present disclosure on the basis of the principle that the inventor is allowed to define terms appropriately for the best explanation.

Therefore, the description proposed herein is just a preferable example for the purpose of illustrations only, not intended to limit the scope of the disclosure, so it should be understood that other equivalents and modifications could be made thereto without departing from the scope of the disclosure.

The subject matter of the present description will now be described more fully hereinafter with reference to the accompanying drawings, which form a part thereof, and which show, by way of illustration, specific exemplary embodiments. An embodiment or implementation described herein as “exemplary” is not to be construed as preferred or advantageous, for example, over other embodiments or implementations; rather, it is intended to reflect or indicate that the embodiment(s) is/are “example” embodiment(s). Subject matter can be embodied in a variety of different forms and, therefore, covered or claimed subject matter is intended to be construed as not being limited to any exemplary embodiments set forth herein; exemplary embodiments are provided merely to be illustrative. Likewise, a reasonably broad scope for claimed or covered subject matter is intended. Among other things, for example, subject matter may be embodied as methods, devices, components, or systems. Accordingly, embodiments may, for example, take the form of hardware, software, firmware, or any combination thereof (other than software per se). The following detailed description is, therefore, not intended to be taken in a limiting sense.

Throughout the specification and claims, terms may have nuanced meanings suggested or implied in context beyond an explicitly stated meaning. Likewise, the phrase “in one embodiment” as used herein does not necessarily refer to the same embodiment and the phrase “in another embodiment” as used herein does not necessarily refer to a different embodiment. It is intended, for example, that claimed subject matter include combinations of exemplary embodiments in whole or in part.

The terminology used below may be interpreted in its broadest reasonable manner, even though it is being used in conjunction with a detailed description of certain specific examples of the present disclosure. Indeed, certain terms may even be emphasized below; however, any terminology intended to be interpreted in any restricted manner will be overtly and specifically defined as such in this Detailed Description section. Both the foregoing general description and the following detailed description are exemplary and explanatory only and are not restrictive of the features, as claimed.

In this disclosure, the term “based on” means “based at least in part on.” The terms including the ordinal number such as “first”, “second” and the like, may be used to distinguish one element from another among various elements, but not intended to limit the elements by the terms. The singular forms “a,” “an,” and “the” include plural referents unless the context dictates otherwise. The term “exemplary” is used in the sense of “example” rather than “ideal.” The term “or” is meant to be inclusive and means either, any, several, or all of the listed items. The terms “comprises,” “comprising,” “includes,” “including,” or other variations thereof, are intended to cover a nonexclusive inclusion such that a process, method, or product that comprises a list of elements does not necessarily include only those elements, but may include other elements not expressly listed or inherent to such a process, method, article, or apparatus. Relative terms, such as, “substantially” and “generally,” are used to indicate a possible variation of +5% of a stated or understood value.

In addition, throughout the specification, when a portion is referred to as being “connected” or “coupled” to another portion, it is not limited to the case that they are “directly connected” or “directly coupled”, but it also includes the case where they are “indirectly connected” or “indirectly coupled” with one or more elements being arranged between them.

Additionally, in describing the present disclosure, when it is deemed that a detailed description of relevant known elements or functions renders the key subject matter of the present disclosure ambiguous, the detailed description is omitted herein.

In addition, throughout the specification, when a portion is referred to as being “connected” to another portion, it is not limited to the case that they are “directly connected”, but it also includes the case where they are “indirectly connected” with another element being interposed between them.

Hereinafter, preferred embodiments of the present disclosure will be described in detail with reference to the accompanying drawings.

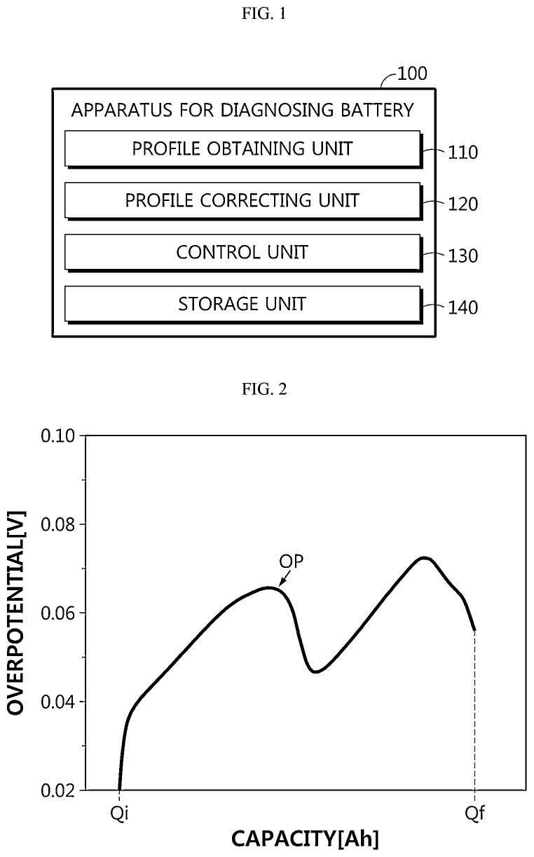

FIG. 1 is a diagram schematically showing an apparatus 100 for diagnosing a battery according to an embodiment of the present disclosure.

Referring to FIG. 1, the apparatus 100 for diagnosing a battery may include a profile obtaining unit 110, a profile correcting unit 120, and a control unit 130.

The profile obtaining unit 110 may be configured to obtain each of a plurality of battery profiles BP indicating the correspondence relationship between the voltage and capacity of each of a plurality of batteries.

Here, the battery refers to an independent cell that has a negative terminal and a positive terminal and is physically separable. As an example, a lithium-ion battery or a lithium polymer battery may be considered as a battery. Additionally, the type of battery may be a cylindrical type, a prismatic type, or a pouch type. Additionally, the battery may mean a battery bank, a battery module or a battery pack in which a plurality of cells are connected in series and/or parallel. Below, for convenience of explanation, the battery is explained as meaning one independent cell.

Specifically, the battery profile BP is a profile that represents the correspondence relationship between voltage (V) and capacity (Q) when the SOC of the battery is charged from 0% to 100%. Alternatively, the battery profile BP may also represent the correspondence relationship between voltage (V) and capacity (Q) when the SOC of the battery is discharged from 100% to 0%. For example, the battery profile BP can be generated based on the voltage and capacity while the battery is being charged or discharged at a constant C-rate. Here, the C-rate must be kept constant while the battery profile BP is generated. That is, when the C-rate for charging and discharging is set, the set C-rate remains constant until charging and discharging ends.

For example, the profile obtaining unit 110 may directly receive the battery profile BP from a source outside of the obtaining unit 110. That is, the profile obtaining unit 110 can obtain the battery profile BP by receiving the battery profile BP by being connected to the source outside by a wire(s) and/or wirelessly.

As another example, the profile obtaining unit 110 may receive battery information about the voltage (V) and capacity (Q) of the battery. Additionally, the profile obtaining unit 110 may generate a battery profile BP based on the received battery information. That is, the profile obtaining unit 110 can obtain the battery profile BP by directly generating the battery profile BP based on the received battery information.

The profile obtaining unit 110 may be connected to enable communication with the profile correcting unit 120. For example, the profile obtaining unit 110 may be connected to the profile correcting unit 120 by wire(s) and/or wirelessly. The profile obtaining unit may transmit the obtained battery profile BP to the profile correcting unit 120.

The profile correcting unit 120 may be configured to generate a plurality of corrected profiles CP by correcting the plurality of battery profiles BP based on the preset overpotential profile OP.

Here, the overpotential profile OP is a profile that represents the correspondence relationship between capacity and overpotential. For example, the overpotential profile OP is a profile indicating overpotential according to capacity. Specifically, the overpotential profile OP may be a profile representing the voltage difference per capacity between the battery profile of the reference battery for the reference C-rate and the battery profile of the reference battery for the target C-rate set for the plurality of batteries.

For example, it is assumed that the reference C-rate is 0.05 C and the target C-rate is 0.3 C. When the reference battery is charged (or discharged) to 0.05 C, the first battery profile can be obtained. When the reference battery is charged (or discharged) to 0.3 C, the second battery profile can be obtained. The voltage difference between the first battery profile and the second battery profile for the same capacity can be calculated as overpotential. That is, the overpotential per capacity of the first battery profile and the second battery profile can be calculated, and the overpotential profile OP representing the correspondence relationship between capacity and overpotential can be generated. In general, if the battery is charged and discharged at a C-rate greater than the reference C-rate, the measured voltage of the battery may include an overpotential. Therefore, the overpotential profile OP may be generated by removing the battery profile based on the reference C-rate from the battery profile based on the target C-rate (e.g. calculating the voltage difference per capacity). FIG. 2 is a diagram schematically showing an overpotential profile OP according to an embodiment of the present disclosure.

Specifically, FIG. 2 is a diagram showing the overpotential profile OP generated in the process of discharging the reference battery from start capacity (Qi) to end capacity (Qf). The first battery profile can be generated as the reference battery is discharged from start capacity (Qi) to end capacity (Qf) at the reference C-rate. In addition, the second battery profile can be generated as the reference battery is discharged from start capacity (Qi) to end capacity (Qf) at the target C-rate. The overpotential profile OP can be generated by calculating the voltage difference per discharge capacity value between the first battery profile and the second battery profile from start capacity value (Qi) to end capacity value

(Qf). For example, the overpotential profile OP may be generated by subtracting a numerical voltage value of the first battery BP with a numerical voltage value of the second battery profile BP from the start capacity (Qi) to end capacity (Qf) or vice versa.

The profile correcting unit 120 may be configured to generate a plurality of corrected profiles CP by calculating the voltage difference per capacity value between each of the plurality of battery profiles BP and the overpotential profile OP.

Specifically, the profile correcting unit 120 may remove the overpotential profile OP from the battery profile BP. For example, the profile correcting unit 120 may calculate the difference between a voltage value of the battery profile BP and an overpotential voltage value of the overpotential profile OP at the same capacity value. The profile correcting unit 120 may generate a corrected profile CP by calculating the difference between the voltage of the battery profile BP and the overpotential voltage value of the overpotential profile OP at all capacity values. In other words, the corrected profile CP is a profile in which the overpotential profile OP is removed from the battery profile BP.

For example, it is assumed that the overpotential profile OP is a profile based on the voltage difference of the first battery profile of the reference battery for 0.05 C and the second battery profile of the reference battery for 0.3 C. The corrected profile CP generated by the difference between the battery profile BP and the overpotential profile OP for 0.3 C may be a profile corresponding to 0.05 C. That is, since the overpotential of the overpotential profile OP is removed from the battery profile BP for 0.3 C, the corrected profile CP for 0.05 C may be derived.

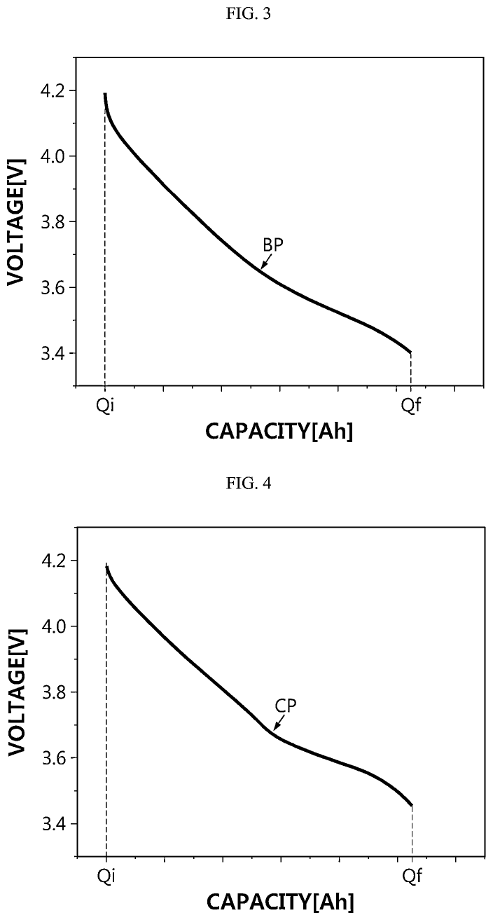

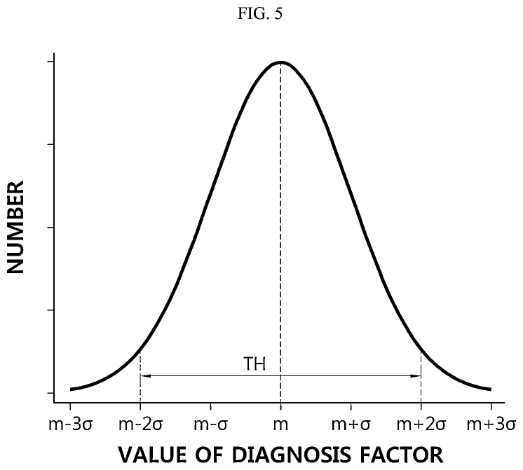

FIG. 3 is a diagram schematically showing a battery profile BP according to an embodiment of the present disclosure. FIG. 4 is a diagram schematically showing a corrected profile CP according to an embodiment of the present disclosure.

Specifically, the battery profile BP in FIG. 3 is a profile obtained when the battery is discharged at the target C-rate from a start capacity value (Qi) to an end capacity value (Qf).

Referring to FIGS. 2 to 4, the profile correcting unit 120 may generate the corrected profile CP of FIG. 4 by removing the overpotential profile OP of FIG. 2 from the battery profile BP of FIG. 3. Here, the target C-rate corresponding to the battery profile BP in FIG. 3 and the target C-rate corresponding to the overpotential profile OP in FIG. 2 are the same. In other words, the corrected profile CP may be generated based on the battery profile BP and the overpotential profile OP for the same target C-rate.

The profile correcting unit 120 may be configured to generate an adjusted positive electrode profile and an adjusted negative electrode profile corresponding to each battery by adjusting a preset reference profile of a positive electrode and a preset reference profile of a negative electrode to correspond to each of the plurality of corrected profiles CP.

The reference profile of a positive electrode may be a profile representing a correspondence relationship between the capacity and voltage of a positive electrode of a battery based on a preset reference profile of a positive electrode (or cathode) cell. For example, the reference positive electrode cell may be a positive electrode of a half-cell coin-type battery or a positive electrode of a three-electrode cell. Additionally, the reference profile of a negative electrode may be a profile representing a correspondence relationship between the capacity and voltage of the preset reference negative electrode cell to correspond to the negative electrode of the battery. For example, the reference negative electrode cell may be a negative electrode of a half-cell coin-type battery or a negative electrode of a three-electrode cell.

Specifically, the profile correcting unit 120 may adjust the reference profile of a positive electrode and the reference profile of a negative electrode to correspond to the corrected profile CP. More specifically, the profile correcting unit 120 may adjust the reference profile of the positive electrode and the reference profile of the negative electrode to generate an adjusted profile of the positive electrode and an adjusted profile of the negative electrode. Additionally, the profile correcting unit 120 may generate a comparison profile of a full-cell from the adjusted profile of the positive electrode and the adjusted profile of the negative electrode. The profile correcting unit 120 may adjust the reference profile of the positive electrode and the reference profile of the negative electrode profile until the comparison profile of the full-cell corresponds to the corrected profile CP.

For example, the profile correcting unit 120 may generate a plurality of comparison profiles of the full-cell profile by shifting the reference profile of the positive electrode and the reference profile of the negative electrode or by scaling the capacities thereof, and may specify a comparison profile of the full-cell with minimized error with the corrected profile CP among the plurality of comparison profiles of the full-cell. Also, an adjusted profile of a positive electrode and an adjusted profile of a negative electrode corresponding to the specified comparison profile of a full-cell be determined.

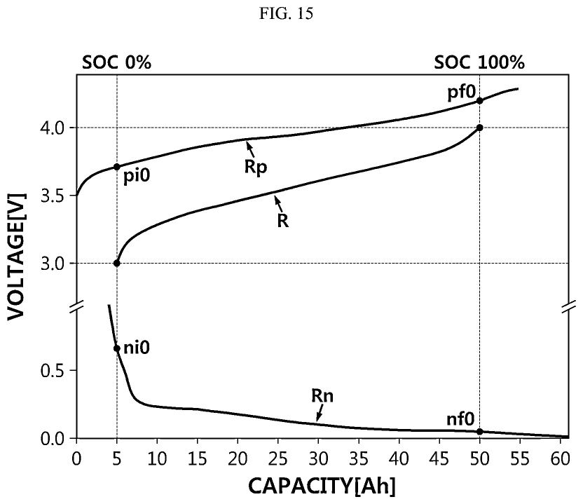

In relation to this, a more specific embodiment in which the profile correcting unit 120 determines the positive electrode profile of the battery by adjusting the reference profile of the positive electrode and the reference profile of the negative electrode to correspond to the corrected profile CP will be described later with reference to FIGS. 15 to 22.

The control unit 130 may be configured to extract a diagnostic factor for each battery from at least one of the adjusted profile of the positive electrode and the adjusted profile of the negative electrode.

For example, the control unit 130 may extract a diagnostic factor related to the positive electrode from the adjusted profile of the positive electrode. Additionally, the control unit 130 may extract a diagnostic factor related to the negative electrode from the adjusted profile of the negative electrode. Additionally, the control unit 130 may extract a diagnostic factor related to positive and negative electrodes by considering both the diagnostic factor related to the positive electrode and the diagnostic factor related to the negative electrode. For convenience of explanation, specific examples regarding the diagnostic factor will be described later.

For example, the control unit 130 may extract a diagnostic factor for each of the plurality of batteries based on the adjusted profile of the positive electrode and/or the adjusted profile of the negative electrode corresponding to each of the plurality of batteries. Here, it should be noted that the diagnostic factors extracted for the plurality of batteries are the same item. In other words, the control unit 130 can extract a plurality of diagnostic factors to correspond to the plurality of batteries.

The control unit 130 may be configured to diagnose the state of the plurality of batteries based on the extracted plurality of diagnostic factors.

Specifically, because the plurality of diagnostic factors are values for the same item, the control unit 130 may distinguish between a normal battery and an abnormal battery by considering the distribution of the plurality of diagnostic factors.

For example, the control unit 130 may compare the plurality of diagnostic factors with a threshold range TH using a statistical analysis method, and diagnose the state of the battery as normal state or abnormal state according to the comparison result.

For example, the control unit 130 may be configured to select a diagnostic factor that is outside the threshold range TH among the plurality of diagnostic factors in consideration of the distribution of the plurality of diagnostic factors, and diagnose the state of the battery corresponding to the selected diagnostic factor as an abnormal state. Alternatively, the control unit 130 may be configured to select a diagnostic factor included in the threshold range TH among the plurality of diagnostic factors and diagnose the state of the battery corresponding to the selected diagnostic factor as a normal state.

FIG. 5 is a diagram schematically showing the distribution of diagnostic factors according to an embodiment of the present disclosure. Specifically, FIG. 5 is a diagram illustrating an embodiment in which the distribution of a plurality of diagnostic factors follows a normal distribution. For example, if the average value of the diagnostic factors is m and the standard deviation is σ, the threshold range TH can be set to a range of m−2σ or more and m+2σ or less. The control unit 130 may classify the plurality of diagnostic factors into diagnostic factors that belong to the threshold range TH and diagnostic factors that do not belong to the threshold range TH. Additionally, the control unit 130 may diagnose the state of the battery corresponding to the diagnostic factor belonging to the threshold range TH as a normal state, and diagnose the state of the battery corresponding to the diagnostic factor not belonging to the threshold range TH as an abnormal state.

In the above, for convenience of explanation, an embodiment of the threshold range TH set based on 20 has been described, but it should be noted that the threshold range TH is not limited to the range of m−2σ to m+2σ.

The apparatus 100 for diagnosing a battery according to the present disclosure may diagnose the state of the battery based on the corrected profile CP in which the overpotential is removed from the battery profile BP, so there is an advantage in that charging and discharging at the reference C-rate is not forced to diagnose the state of the battery. In other words, since the state of the battery can be diagnosed even if the battery is charged and discharged at a C-rate other than the reference C-rate, the state of the battery can be diagnosed quickly without restrictions on charging and discharging conditions.

In addition, the apparatus 100 for diagnosing a battery has an advantage of quickly distinguishing between a normal battery and an abnormal battery by relatively comparing the states of the plurality of batteries based on the distribution of the plurality of diagnostic factors.

Further, the control unit 130 included in the apparatus 100 for diagnosing a battery may optionally include a processor, an application-specific integrated circuit (ASIC), other chipset, a logic circuit, a register, a communication modem, a data processing device, etc. known in the art to execute various control logics performed in the present disclosure. Also, when the control logic is implemented as software, the control unit 130 may be implemented as a set of program modules. At this time, the program module may be stored in the memory and executed by the control unit 130. The memory may be inside or outside the control unit 130 and may be connected to the control unit 130 by various well-known means.

In addition, the apparatus 100 for diagnosing a battery may further include a storage unit 140. The storage unit 140 may store data necessary for operation and function of each component of the apparatus 100 for diagnosing a battery, data generated in the process of performing the operation or function, or the like. The storage unit 140 is not particularly limited in its kind as long as it is a known information storage means that can record, erase, update and read data. As an example, the information storage means may include RAM, flash memory, ROM, EEPROM, registers, and the like. In addition, the storage unit 140 may store program codes in which processes executable by the control unit 130 are defined.

The apparatus 100 disclosed in connection with embodiments of FIGS. 1-18 and the various elements therein comprised, which enable the implementation of methods and processes in accordance with the present disclosure, may be implemented by a processor using a plurality of microprocessors executing software or firmware, or may be implemented using one or more application specific integrated circuits (ASICs) and related software. In other examples, the apparatus 100 the various elements therein comprised, which enable the implementation of methods and processes in connection with embodiments of FIGS. 1-18, may be implemented using a combination of ASICs, discrete electronic components (e.g., transistors), and microprocessors. In some embodiments, components shown as separate may be replaced by a single component. In addition, some of the components displayed may be additional, or may be replaced by other components.

For example, the storage unit 140 can store the plurality of battery profiles BP, the overpotential profile OP, the plurality of corrected profiles CP, the reference profile of the positive electrode, the reference profile of the negative electrode, the adjusted positive electrode profile, the adjusted negative electrode profile, and the plurality of diagnostic factors.

In the following, the conventional battery state diagnosis method and the battery state diagnosis method using the apparatus 100 for diagnosing a battery will be comparatively explained.

For example, if low rate charging and discharging of 0.05 C is forced to obtain the battery profile BP, it may take about 20 hours just to obtain the battery profile BP. Additionally, the process of diagnosing the state of the battery according to the obtained battery profile BP may also take additional time. That is, according to the conventional method, since a considerable amount of time is required in the process of obtaining the battery profile BP, there is a problem in that the state of the battery cannot be quickly diagnosed.

On the other hand, if the battery is charged and discharged at 0.3 C as in an embodiment of the present disclosure, the battery profile BP can be obtained in about 3 hours. In other words, according to an embodiment of the present disclosure, the time required to obtain the battery profile BP can be dramatically reduced compared to the conventional method. However, since the battery profile BP obtained in this way may include an overpotential, the apparatus 100 for diagnosing a battery may generate a corrected profile CP by removing the overpotential from the battery profile BP, and diagnose the state of the battery according to the generated corrected profile CP. Therefore, even considering the additional time required in the process of generating the corrected profile CP and diagnosing the state of the battery, there is an advantage in that the apparatus 100 for diagnosing a battery can diagnose the state of the battery very quickly compared to the conventional method.

The overpotential profile OP may be stored in advance for each of the plurality of C-rates.

For example, a plurality of overpotential profiles OP may be provided, and the C-rates respectively corresponding to the plurality of overpotential profiles OP may be different. Accordingly based on the unit C-rate, an overpotential profile OP corresponding to each C-rate may be stored in advance.

Additionally, an overpotential profile OP for C-rate that is not experimentally obtained may be obtained and stored through interpolation or extrapolation between similar overpotential profiles OP. For example, the profile correcting unit 120 may generate overpotential profiles OP for various C-rates in addition to the pre-stored overpotential profile OP through interpolation or extrapolation, and store the generated overpotential profile OP in the storage unit 140. For example, if the overpotential profile OP corresponding to 1 C and the overpotential profile OP corresponding to 1.2 C are stored in advance, an overpotential profile OP corresponding to 1.1 C can be additionally obtained based on the difference between the two overpotential profiles OP.

The profile correcting unit 120 may be configured to select an overpotential profile OP corresponding to the target C-rate among the plurality of overpotential profiles OP stored in advance.

Here, the target C-rate is a C-rate set for the battery. For example, if a plurality of battery profiles BP is obtained in the process of charging the plurality of batteries at 0.3 C, the target C-rate is 0.3 C. The profile correcting unit 120 can select the overpotential profile OP corresponding to 0.3 C among the plurality of overpotential profiles OP.

The profile correcting unit 120 may be configured to generate a plurality of corrected profiles CP using the selected overpotential profile OP.

For example, the profile correcting unit 120 may generate a plurality of corrected profiles CP by calculating the difference between each of the plurality of battery profiles BP and the selected overpotential profile OP. That is, the profile correcting unit 120 can obtain a plurality of corrected profiles CP from which overpotential is commonly removed.

Because overpotential may include noise, the battery profile BP having overpotential may not accurately reflect the current state of the battery. Therefore, the apparatus 100 for diagnosing a battery according to an embodiment of the present disclosure may remove the overpotential included in the battery profile BP using the overpotential profile OP corresponding to the target C-rate. In other words, the apparatus 100 for diagnosing a battery has an advantage of more accurately diagnosing the state of the battery based on the corrected profile CP from which overpotential is removed.

For example, a battery and the apparatus 100 for diagnosing a battery may be provided in the final application. In this example, the final application may refer to a final product to which the apparatus 100 for diagnosing a battery may be applied, and may include a motorcycle, vehicle, or ESS (Energy storage system). In other words, the apparatus 100 for diagnosing a battery may be an on-board diagnostic device provided in the final application. In this case, the C-rate for the battery in the final application may not be included in the plurality of C-rates corresponding to the pre-stored overpotential profile OP.

In other words, in a situation where the battery is actually operated in the final application, the C-rate for the battery may vary based on various environmental factors.

Therefore, the C-rate for the battery may not be included in the plurality of C-rates corresponding to the pre-stored overpotential profile OP. In this case, if the overpotential included in the battery profile BP is removed based on the battery profile BP and the overpotential profile OP having different C-rates, the generated corrected profile CP may not accurately reflect the state of the battery.

Therefore, if the C-rate for the battery in the final application is not included in the plurality of C-rates, the profile correcting unit 120 may determine two C-rates adjacent to the C-rate for the battery in the final application among the plurality of C-rates that may be pre-stored, and generate an overpotential profile OP corresponding to the C-rate for the battery by interpolating the overpotential profiles corresponding to the determined C-rate.

Additionally, the profile correcting unit 120 may generate a corrected profile CP by removing the overpotential included in the battery profile BP based on the battery profile BP and the generated overpotential profile OP.

Further, a plurality of overpotential profiles (e.g. charge overpotential profiles) corresponding to the charge C-rate and a plurality of overpotential profiles (e.g. discharge overpotential profiles) corresponding to the discharge C-rate may be stored in advance. That is, the plurality of charge overpotential profiles and the plurality of discharge overpotential profiles can be stored independently.

In general, batteries exhibit a hysteresis effect during charging and discharging, so even if the voltage is the same, the charging capacity and discharging capacity may have different values. Therefore, in order to more accurately diagnose the state of the battery, it is desirable to store the plurality of overpotential profiles OP separately according to the charge C-rate and discharge C-rate.

The control unit 130 may determine the charging and discharging process (charging process or discharging process) corresponding to the battery profile BP. For example, the control unit 130 may determine the charging and discharging process of the battery profile BP by comparing the sizes of start capacity and end capacity. Additionally, the control unit 130 may select the corresponding overpotential profile OP based on the determined charging and discharging process and the target C-rate.

The apparatus 100 for diagnosing a battery according to an embodiment of the present disclosure can more accurately diagnose the state of a plurality of batteries by selecting an overpotential profile OP in consideration of the target C-rate and the charging and discharging process.

Below, diagnostic factors that the control unit 130 can select from the adjusted positive electrode profile and/or the adjusted negative electrode profile will be described in detail.

The control unit 130 may be configured to extract at least one of a positive electrode factor based on the adjusted positive electrode profile, a negative electrode factor based on the adjusted negative electrode profile, and a positive and negative electrode factor based on the positive electrode factor and the negative electrode factor as a diagnostic factor.

Here, the adjusted positive electrode profile is the result of adjusting the reference profile of the positive electrode, and the adjusted negative electrode profile is the result of adjusting the reference profile of the negative electrode. Specifically, as described above, the profile adjustment unit can adjust the reference profile of the positive electrode and the reference profile of the negative electrode so that the comparison full-cell profile (generated based on the reference profile of the positive electrode and the reference profile of the negative electrode) corresponds to the corrected profile CP.

The positive electrode factor may include at least one of a positive electrode start potential, a positive electrode end potential, a positive electrode change rate, and a positive electrode loading amount of the battery based on the adjusted positive electrode profile.

The positive electrode start potential is a start potential of the adjusted positive electrode profile, and the positive electrode end potential is an end potential of the adjusted positive electrode profile. Specifically, the positive electrode start potential is a potential value of the positive electrode participation initiating point pi of the adjusted positive electrode profile. The positive electrode end potential is a potential value of the positive electrode participation finalizing point pf of the adjusted positive electrode profile.

The positive electrode change rate (ps) may mean a change rate [%] of the adjusted positive electrode profile with respect to the reference profile of the positive electrode. Specifically, the positive electrode change rate (ps) may be a contraction rate or expansion rate of the adjusted positive electrode profile with respect to the reference profile of the positive electrode. For example, if the adjusted positive electrode profile is 10% shrinkage from the reference profile of the positive electrode, the positive electrode change rate (ps) is 90%. Conversely, if the adjusted positive electrode profile is 10% extension of the reference profile of the positive electrode, the positive electrode change rate (ps) is 110%.

The positive electrode loading amount (p_loading) refers to an amount of positive electrode active material coated on the positive electrode current collector. Since the adjusted positive electrode profile is a profile representing the current state of the positive electrode of the battery, the control unit 130 can calculate the positive electrode loading amount (p_loading) based on the adjusted positive electrode profile. Specifically, the control unit 130 may calculate the positive electrode loading amount (p_loading) in consideration of the positive electrode change rate (ps), a preset reference positive electrode capacity, and a preset reference area. Here, the reference positive electrode capacity may mean a capacity of a preset reference positive electrode cell. The reference area may mean the area of the preset reference positive electrode cell. Specifically, the control unit 130 can calculate the positive electrode loading amount (p_loading) based on the positive electrode change rate (ps), the reference positive electrode capacity, and the reference area using Equation 1 below.

$$p\_loading = ps \times {Q}_{rc} \div {A}_{pc} \qquad [ Equation 1 ]$$

Here, p_loading represents the positive electrode loading amount, and ps represents the positive electrode change rate. Qᵣₑ represents the reference positive electrode capacity, and A_{pc} represents the reference area.

The negative electrode factor may include at least one of a negative electrode start potential, a negative electrode end potential, a negative electrode change rate, and a negative electrode loading amount of the battery based on the adjusted negative electrode profile.

The negative electrode start potential is a start potential of the adjusted negative electrode profile, and the negative electrode end potential is an end potential of the adjusted negative electrode profile. Specifically, the negative electrode start potential is a potential value of the negative electrode participation initiating point ni of the adjusted negative electrode profile. The negative electrode end potential is a potential value of the negative electrode participation finalizing point nf of the adjusted negative electrode profile.

The negative electrode change rate (ns) may mean the change rate [%] of the adjusted negative electrode profile with respect to the reference profile of the negative electrode. Specifically, the negative electrode change rate (ns) may be the contraction rate or expansion rate of the adjusted negative electrode profile with respect to the reference profile of the negative electrode. For example, if the adjusted negative electrode profile is 10% shrinkage from the reference profile of the negative electrode, the negative electrode change rate (ns) is 90%. Conversely, if the adjusted negative electrode profile is 10% extension of the reference profile of the negative electrode, the negative electrode change rate (ns) is 110%.

The negative electrode loading amount (n_loading) refers to the amount of negative electrode active material coated on the negative electrode current collector. Since the adjusted negative electrode profile is a profile indicating the current state of the negative electrode of the battery, the control unit 130 can calculate the negative electrode loading amount (n_loading) based on the adjusted negative electrode profile. Specifically, the control unit 130 may calculate the negative electrode loading amount (n_loading) in consideration of the negative electrode change rate (ns), a preset reference negative electrode capacity, and a preset reference area. Here, the reference negative electrode capacity may mean the capacity of a preset reference negative electrode cell. The reference area may mean the area of a preset reference negative electrode cell. Specifically, the control unit 130 can calculate the negative electrode loading amount (n_loading) based on the negative electrode change rate (ns), the reference negative electrode capacity, and the reference area using Equation 2 below.

$$n\_loading = ns \times {Q}_{ra} \div {A}_{pa} \qquad [ Equation 2 ]$$

Here, n_loading represents the negative electrode loading amount, and ns represents the negative electrode change rate. Qᵣₐ represents the reference negative electrode capacity, and Aₚₐ represents the reference area.

The positive and negative electrode factors may include NP ratio based on the positive electrode loading amount and the negative electrode loading amount.

Specifically, the NP ratio refers to the rate of positive electrode loading amount to negative electrode loading amount. For example, the control unit 130 can calculate the NP ratio using Equation 3 below.

$$np ratio = \frac{n\_loading}{p\_loading} \qquad [ Equation 3 ]$$

Here, np ratio is the NP ratio, p-loading is the positive electrode loading amount according to Equation 1, and n-loading is the negative electrode loading amount according to Equation 2.

The apparatus 100 for diagnosing a battery may extract at least one of the positive electrode start potential, the positive electrode end potential, the positive electrode change rate, the positive electrode loading amount, the negative electrode start potential, the negative electrode end potential, the negative electrode change rate, and the NP ratio as a diagnostic factor. In addition, the apparatus 100 for diagnosing a battery can diagnose the state of the plurality of batteries as normal state or abnormal state based on the distribution per extracted diagnostic factor.

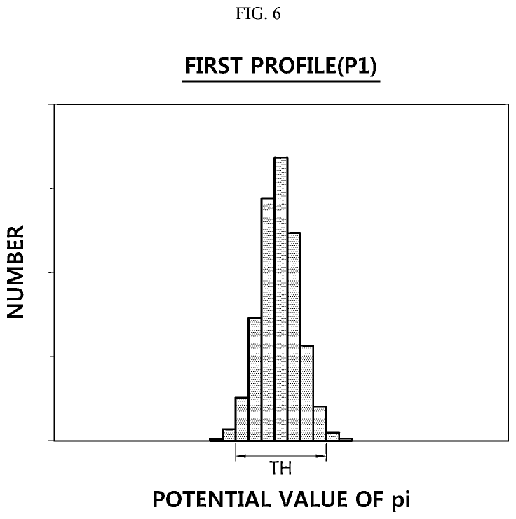

FIGS. 6 to 14 are diagrams showing the distribution of diagnostic factors according to an embodiment of the present disclosure.

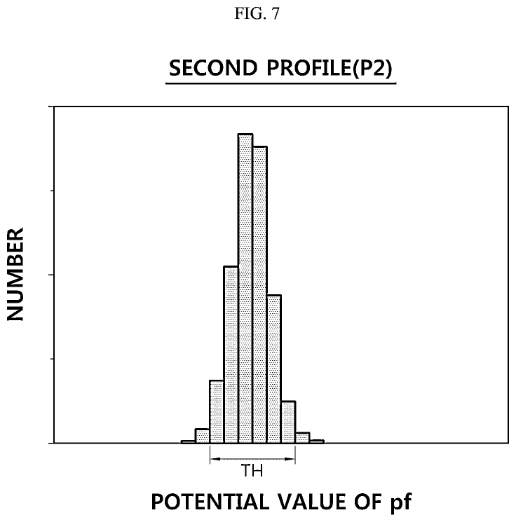

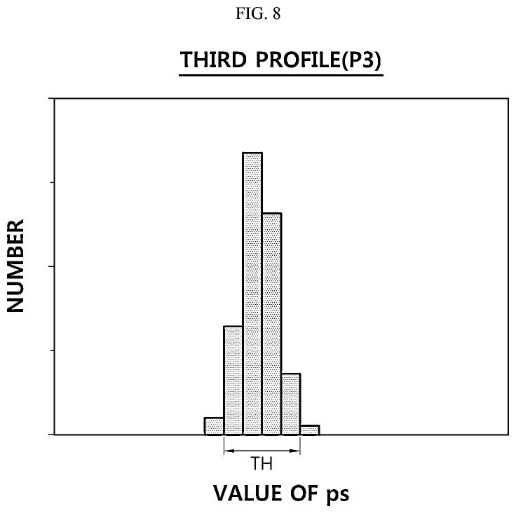

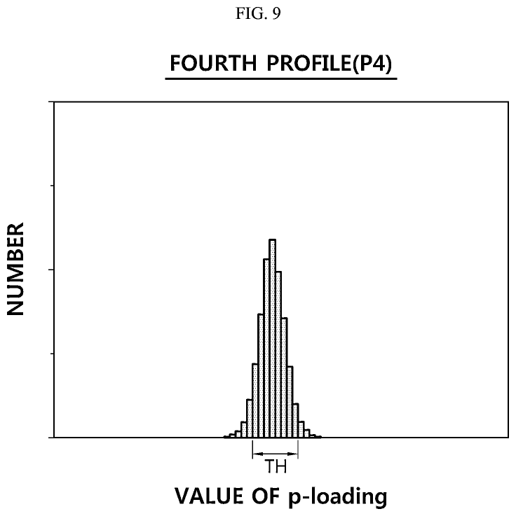

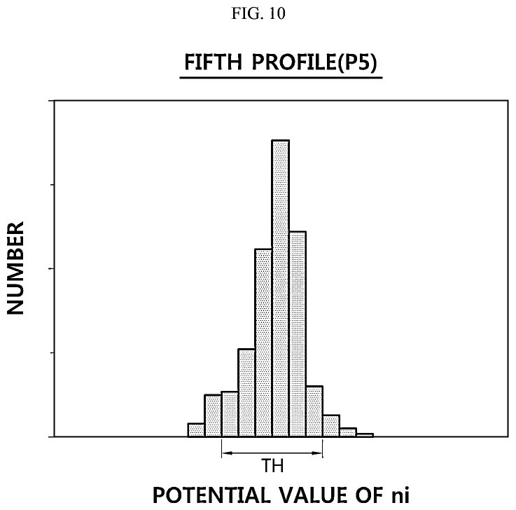

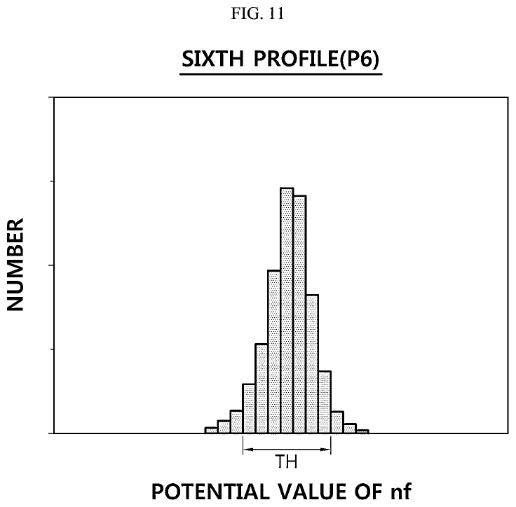

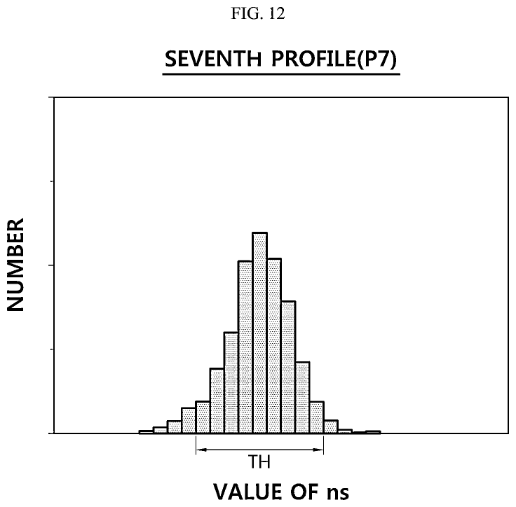

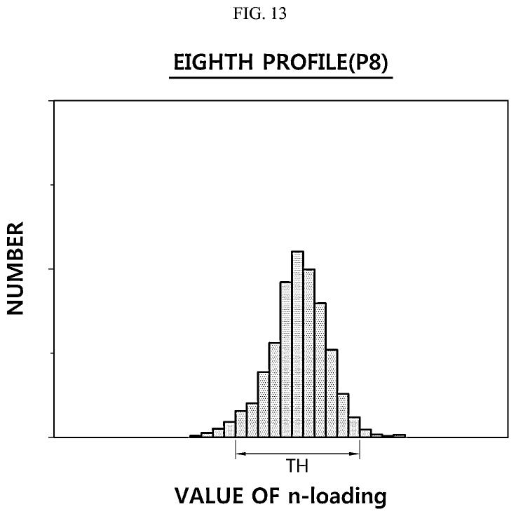

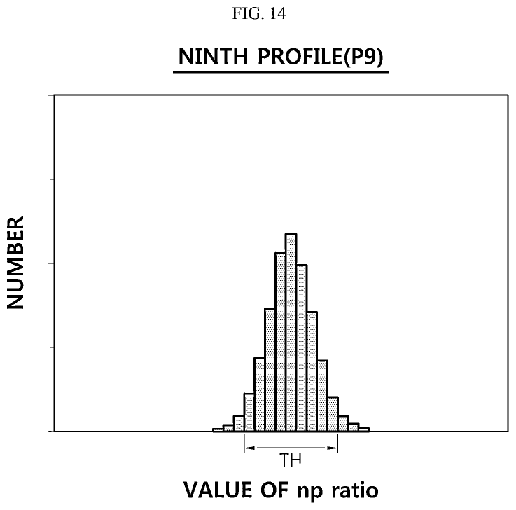

Specifically, FIGS. 6 to 14 are profiles showing the distribution of the diagnostic factor for each of the plurality of batteries. FIG. 6 is a first profile P1 showing the distribution of a plurality of positive electrode start potentials, and FIG. 7 is a second profile P2 showing the distribution of a plurality of positive electrode end potentials. FIG. 8 is a third profile P3 showing the distribution of a plurality of positive electrode change rates, and FIG. 9 is a fourth profile P4 showing the distribution of a plurality of positive electrode loading amounts. FIG. 10 is a fifth profile P5 showing the distribution of a plurality of negative electrode start potentials, and FIG. 11 is a sixth profile P6 showing the distribution of a plurality of negative electrode end potentials. FIG. 12 is a seventh profile P7 showing the distribution of a plurality of negative electrode change rates, and FIG. 13 is an eighth profile P8 showing the distribution of a plurality of negative electrode loading amounts. FIG. 14 is a ninth profile P9 showing the distribution of a plurality of NP ratios. As in the previous embodiment, in FIGS. 6 to 14, it is assumed that the 2 standard deviation range for the average value is set as the threshold range TH.

When the diagnostic factor for one diagnosis item is extracted for the plurality of batteries, the control unit 130 can diagnose the state of the plurality of batteries according to the distribution of the extracted plurality of diagnostic factors.

Specifically, the control unit 130 can extract diagnostic factors for items of interest among the plurality of diagnosis items and diagnose the state of the plurality of batteries based on the extracted plurality of diagnostic factors. Here, the item of interest refers to a diagnostic item selected from the plurality of diagnostic items to diagnose the state of the battery. The item of interest is selected by a user or a preset program, and the control unit 130 can obtain information about the selected item of interest.

For example, in the embodiment of FIG. 6, the item of interest may be selected as the positive electrode start potential. The control unit 130 may extract the positive electrode start potential from the plurality of adjusted positive electrode profiles for the plurality of batteries. Additionally, the control unit 130 may select a positive electrode start potential outside the threshold range TH among the plurality of positive electrode start potentials. That is, the control unit 130 may select a positive electrode start potential that exceeds the upper limit (m+20) of the threshold range TH or is less than the lower limit (m−2σ) of the threshold range TH. Additionally, the control unit 130 may diagnose the state of the battery corresponding to the selected positive electrode start potential as an abnormal state. Conversely, the control unit 130 can diagnose the state of the remaining battery as a normal state.

The apparatus 100 for diagnosing a battery according to an embodiment of the present disclosure can extract diagnostic factors for items of interest and diagnose the state of the plurality of batteries based on the extracted diagnostic factors. Therefore, the apparatus 100 for diagnosing a battery has an advantage of not only quickly diagnosing the state of the battery according to the corrected profile CP with overpotential removed, but also diagnosing the state of the battery more specifically for each subdivided item.

Meanwhile, a plurality of interest items may be selected among the plurality of diagnostic items. The control unit 130 can extract diagnostic factors for each of the plurality of items of interest. Additionally, the control unit 130 can diagnose the state of the plurality of batteries in consideration of the distribution of the plurality of diagnostic factors for each item of interest.

Specifically, the control unit 130 can count the number of items of interest for which the diagnostic factor for each of the plurality of batteries is outside the threshold range TH. Additionally, the control unit 130 can diagnose the state of each battery based on the counted number.

For example, the control unit 130 may diagnose the state of a battery in which the counted number is more than half of the plurality of items of interest as an abnormal state. Conversely, the control unit 130 can diagnose the state of the remaining battery as a normal state. Specifically, when 5 items of interest are selected, the state of the battery with 3 or more items of interest whose diagnostic factor is outside the threshold range TH may be diagnosed as an abnormal state.

For example, referring to FIGS. 6, 7, 10, 11, and 14, among the plurality of diagnostic items, it is assumed that five items of interest of the positive electrode start potential, the positive electrode end potential, the negative electrode start potential, the negative electrode end potential, and the NP ratio are selected. The control unit 130 may select a battery whose positive electrode start potential is outside the threshold range TH in the first profile P1 and increase the counting value for the selected battery by 1. Additionally, the control unit 130 may select a battery whose positive electrode end potential is outside the threshold range TH in the second profile P2 and increase the counting value for the selected battery by 1. The control unit 130 may select a battery whose negative electrode start potential is outside the threshold range TH in the fifth profile P5 and increase the counting value for the selected battery by 1. The control unit 130 may select a battery whose negative electrode end potential is outside the threshold range TH in the sixth profile P6 and increase the counting value for the selected battery by 1. The control unit 130 may select a battery whose NP ratio is outside the threshold range TH in the ninth profile P9 and increase the counting value for the selected battery by 1. The control unit 130 may diagnose the state of a battery with a counting value of 3 or more among the plurality of batteries as an abnormal state, and diagnose the state of the remaining batteries as a normal state.

The apparatus 100 for diagnosing a battery has an advantage of comprehensively diagnosing a plurality of battery states in consideration of the distribution of the plurality of diagnostic items.

Below, an embodiment in which the profile correcting unit 120 adjusts the reference profile of the positive electrode and the reference profile of the negative electrode will be described in detail.

The profile correcting unit 120 may be configured to generate a comparison full-cell profile based on the reference profile of the positive electrode and the reference profile of the negative electrode.

Specifically, the comparison full-cell profile can be generated according to the voltage difference per capacity for the reference profile of the positive electrode and the reference profile of the negative electrode. For example, it is assumed that the voltage of the reference profile of the positive electrode corresponding to a certain capacity x is Vp, and the voltage of the reference profile of the negative electrode is Vn. The voltage of the comparison full-cell profile corresponding to the capacity X can be calculated as “Vp-Vn”. The profile correcting unit 120 may generate a comparison full-cell profile by calculating the voltage difference between the reference profile of the positive electrode and the reference profile of the negative electrode for the entire capacity.

The profile correcting unit 120 may be configured to generate an adjusted positive electrode profile and an adjusted negative electrode profile by adjusting the reference profile of the positive electrode and the reference profile of the negative electrode until the generated comparison full-cell profile corresponds to the corrected profile CP.

Specifically, the profile correcting unit 120 may calculate an error between the comparison full-cell profile and the corrected profile CP. Additionally, the profile correcting unit 120 may adjust the reference profile of the positive electrode and the reference profile of the negative electrode until the error between the comparison full-cell profile and the corrected profile CP is minimized. If the comparison full-cell profile that minimizes the error with the corrected profile CP is determined, the adjusted positive electrode profile and the adjusted negative electrode profile, which are the basis of the determined comparison full-cell profile, may be estimated as the positive electrode profile and the negative electrode profile that represent the current state of the battery. With current technology, there is a problem that it is not possible to directly obtain the positive electrode profile and the negative electrode profile indicating the current state of the battery without directly disassembling the battery. Therefore, it can be strongly assumed that the adjusted positive electrode profile and the adjusted negative electrode profile, which are the basis of the comparison full-cell profile determined through the adjustment process, are the positive electrode profile and the negative electrode profile that reflect the current state of the battery.

Hereinafter, with reference to FIGS. 15 to 22, an embodiment in which the profile correcting unit 120 adjusts the reference profile of the positive electrode and the reference profile of the negative electrode will be described in more detail.

FIGS. 15 to 22 are diagrams for explaining the process of adjusting a reference profile of the positive electrode and a reference profile of the negative electrode according to an embodiment of the present disclosure. Below, for convenience of explanation, the corrected profile CP according to an embodiment of the present disclosure is described as a measurement full-cell profile M.

FIG. 15 is a graph referenced to for explaining an example of the reference profile of the positive electrode Rp and the reference profile of the negative electrode Rn, respectively. In the graph of FIG. 15, the horizontal axis (X-axis) represents capacity (Ah) and the vertical axis (Y-axis) represents voltage (V).

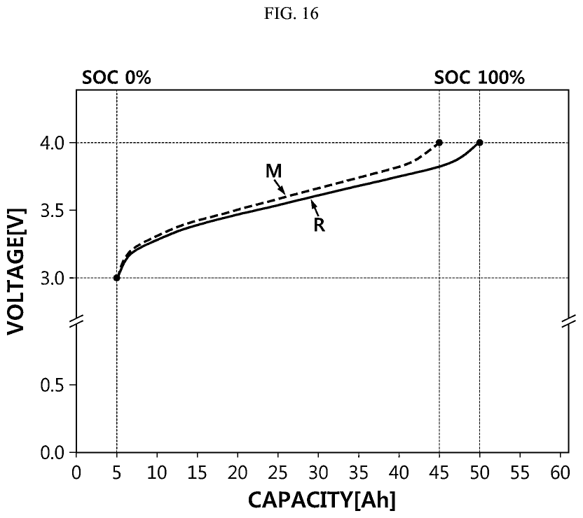

FIG. 16 is a graph referenced to for explaining an example of the measurement full-cell profile M of the target battery. In the graph of FIG. 16, the horizontal axis (X-axis) represents capacity (Ah) and the vertical axis (Y-axis) represents voltage (V).

The profile correcting unit 120 may be configured to compare the measurement full-cell profile M and at least one comparison full-cell profile. Here, the comparison full-cell profile (R) may be the result of synthesizing (combining) the adjusted positive electrode profile and the adjusted negative electrode profile based on the reference profile of the n positive electrode Rp and the reference profile of the negative electrode Rn, respectively, stored in the storage unit 140.

In other words, when the reference full-cell profile R is the result of subtracting a part of the reference profile of the negative electrode Rn from a part of the reference profile of the positive electrode Rp, the comparison full-cell profile can be said to be the result of subtracting a part of the adjusted negative electrode profile from a part of the adjusted positive electrode profile.

The profile correcting unit 120 may generate at least one comparison full-cell profile by directly adjusting the reference profile of the positive electrode Rp and the reference profile of the negative electrode Rn. Alternatively, at least one comparison full-cell profile may be secured in advance based on the reference profile of the positive electrode Rp and the reference profile of the negative electrode Rn and stored in the storage unit 140. In this case, the profile correcting unit 120 may obtain the comparison full-cell profile in the form of accessing the storage unit 140 and reading the comparison full-cell profile.

The profile correcting unit 120 may generate a plurality of comparison full-cell profiles from the reference profile of the positive electrode Rp and the reference profile of the negative electrode Rn by repeating the process of adjusting each of the reference profile of the positive electrode Rp and the reference profile of the negative electrode Rn to various levels and then synthesizing them. The comparison full-cell profile can also be called an ‘adjusted reference full-cell profile’.

The profile correcting unit 120 may specify any one comparison full-cell profile that has a minimum error with the measurement full-cell profile M among the plurality of comparison full-cell profiles.

Next, the profile correcting unit 120 may determine that the adjusted positive electrode profile and the adjusted negative electrode profile mapped to the specified comparison full-cell profile are the positive electrode profile and the negative electrode profile of the battery. In the following, it should be noted that the positive electrode profile is a finally determined adjusted positive electrode profile, and the negative electrode profile is a finally determined adjusted positive electrode profile.

In relation to this, various methods known at the filing time of the present disclosure can be employed to determine the error between two profiles, each of which can be expressed in a two-dimensional coordinate system. For example, the integral value of the absolute value of the area between two profiles or RMSE (Root Mean Square Error) can be used as the error between two profiles.

According to this configuration of the present disclosure, various state information about the battery can be obtained based on the finally determined positive electrode profile and negative electrode profile. The finally determined positive electrode profile and negative electrode profile may be mapped to the comparison full-cell profile mapped to the minimum error. In particular, it can be said that the comparison full-cell profile based on the finally determined positive electrode profile and negative electrode profile is almost identical to measurement full-cell profile M in terms of shape.

Therefore, according to the present disclosure, the positive electrode profile and the negative electrode profile of the battery can be obtained even without disassembling the battery.

If the battery is a new battery, the positive electrode profile and the negative electrode profile of the battery can be analyzed to more easily diagnose whether a defect has occurred in the battery and, if so, what type of defect it is.

If the battery is being used after it has been verified to be a good product, it is possible to determine the extent to which the battery has deteriorated for each deterioration item through the positive electrode profile and the negative electrode profile of the battery.

Moreover, according to an embodiment of the present disclosure, the positive electrode profile and the negative electrode profile of the battery can be obtained in a simple manner. Even if only one reference profile of the positive electrode Rp and one reference profile of the negative electrode Rn are stored in the storage unit 140, the present disclosure may be implemented. That is, there is no need to store a plurality of reference profiles of the positive electrode Rp and/or a plurality of reference profiles of the negative electrode Rn in the storage unit 140. Accordingly, the storage capacity of the storage unit 140 does not need to be high, and there is no need to conduct numerous preliminary tests required to secure a plurality of reference profile of the positive electrode Rp and/or a plurality of reference profiles of the n negative electrode Rn.

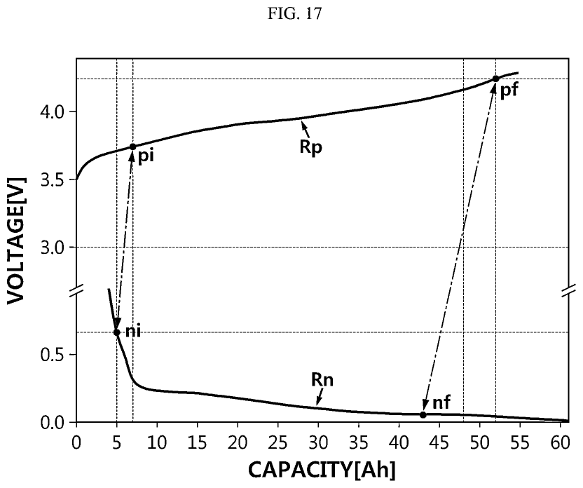

FIGS. 17 to 19 are diagrams referenced to for explaining an example of a procedure for generating a comparison full-cell profile used for comparison with the measurement full-cell profile M according to an embodiment of the present disclosure.

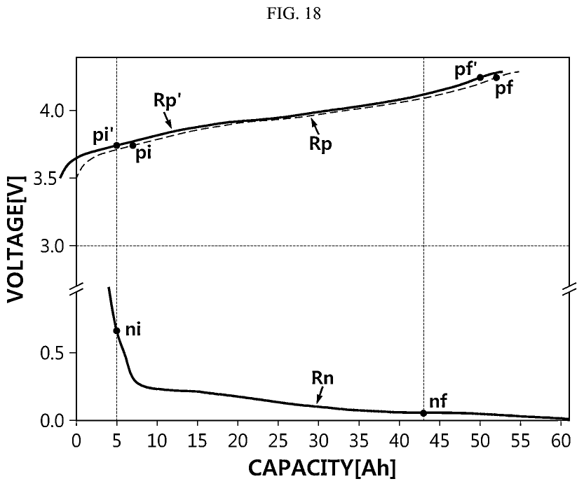

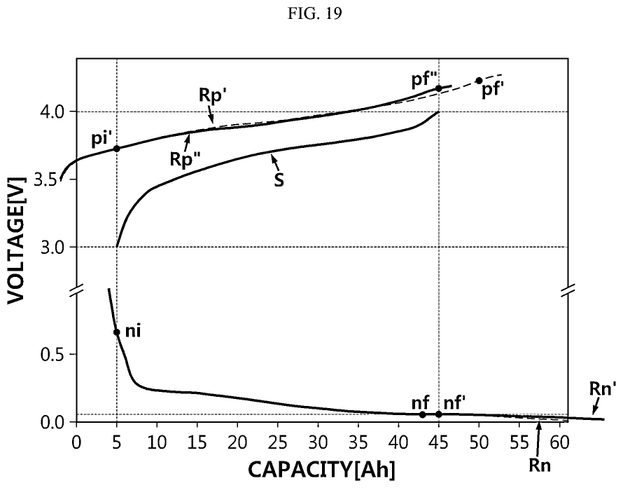

The procedure for generating a comparison full-cell profile, which will be described with reference to FIGS. 17 to 19, proceeds in the following order: a first routine that sets four points (positive electrode participation initiating point, positive electrode participation finalizing point, negative electrode participation initiating point, negative electrode participation finalizing point) to correspond to the voltage range of interest (see FIG. 17), a second routine that performs profile shifting (see FIG. 18), and a third routine that performs capacity scaling (see FIG. 19). That is, the procedure for generating a comparison full-cell profile according to an embodiment of the present disclosure includes the first to third routines.

First, referring to FIG. 17, the reference profile of the positive electrode Rp and the reference profile of the negative electrode Rn are the same as those shown in FIG. 15. The profile correcting unit 120 determines a positive electrode participation initiating point pi, a positive electrode participation finalizing point pf, a negative electrode participation initiating point ni, and a negative electrode participation finalizing point nf on the reference profile of the positive electrode Rp and the reference profile of the negative electrode Rn.

Either the positive electrode participation initiating point pi or the negative electrode participation initiating point ni depends on the other.

As an example, the profile correcting unit 120 divides the positive electrode voltage range from the starting point of the reference profile of the positive electrode Rp to the end point (or second setting voltage) into a plurality of micro voltage sections, and then set the boundary point of two adjacent micro voltage sections among the plurality of micro voltage sections as the positive electrode participation initiating point pi. Each micro voltage section may have a predetermined size (e.g., 0.01 V). Next, the profile correcting unit 120 may set a point on the reference profile of the negative electrode Rn, which is smaller than the positive electrode participation initiating point pi by the first setting voltage (e.g., 3 V), as the negative electrode participation initiating point ni.

As another example, the profile correcting unit 120 may divide the negative electrode voltage range from the start point to the end point of the reference profile of the negative electrode Rn into a plurality of micro voltage sections of a predetermined size, and then set the boundary point of two adjacent micro voltage sections among the plurality of micro voltage sections as the negative electrode participation initiating point ni. Next, the profile correcting unit 120 may search for a point, which is greater than the negative electrode participation initiating point ni by the first setting voltage, from the reference profile of the positive electrode Rp and set the searched point as the positive electrode participation initiating point pi.

Either the positive electrode participation finalizing point pf and the negative electrode participation finalizing point nf depends on the other.

As an example, the profile correcting unit 120 may divide the voltage range from the second setting voltage to the end point of the reference profile of the positive electrode Rp into a plurality of micro voltage sections of a predetermined size, and then set the boundary point of two adjacent micro voltage sections among the plurality of micro voltage sections as the positive electrode participation finalizing point pf. Next, the profile correcting unit 120 may set a point on the reference profile of the negative electrode Rn, which is smaller than the positive electrode participation finalizing point pf by a second setting voltage (e.g., 4 V), as the negative electrode participation finalizing point nf.

As another example, the profile correcting unit 120 may divide the negative electrode voltage range from the start point to the end point of the reference profile of the negative electrode Rn into a plurality of micro voltage sections of a predetermined size, and then set the boundary point of two adjacent micro voltage sections among the plurality of micro voltage sections as the negative electrode participation finalizing point nf. Next, the profile correcting unit 120 may search for a point, which is greater than the negative electrode participation finalizing point nf by a second setting voltage, from the reference profile of the positive electrode Rp and set the searched point as the positive electrode participation finalizing point pf.

If the determination of the positive electrode participation initiating point pi, the positive electrode participation finalizing point pf, the negative electrode participation initiating point ni, and the negative electrode participation finalizing point nf is completed, the profile correcting unit 120 shifts at least one of the reference profile of the positive electrode Rp and the reference profile of the negative electrode Rn to the left or right along the horizontal axis.

Referring to FIG. 18, the profile correcting unit 120 may shift the reference profile of the positive electrode Rp and/or the reference profile of the negative electrode Rn so that the capacity values of the positive electrode participation initiating point pi and the negative electrode participation initiating point ni match.

Alternatively, the profile correcting unit 120 may shift the reference profile of the positive electrode Rp and/or the reference profile of the negative electrode Rn so that the voltages of the positive electrode participation finalizing point pf and the negative electrode participation finalizing point nf match.

FIG. 18 shows the situation that the adjusted reference profile of the positive electrode Rp′ is generated by shifting only the reference profile of the positive electrode Rp to the left, and as a result, the voltage of the positive electrode participation initiating point pi′ matches the voltage of the negative electrode participation initiating point ni. The adjusted reference profile of the positive electrode Rp′ is the result of applying an adjustment procedure of shifting to the left by the voltage difference between the positive electrode participation initiating point pi and the negative electrode participation initiating point ni to the reference profile of the positive electrode Rp. Therefore, the two points pi, pi′ differ only in capacity value and have the same voltage. The two points pf, pf′ differ only in capacity value and have the same voltage.

When the adjustment result profiles Rp′, Rn in which at least one of the reference profile of the positive electrode Rp and the reference profile of the negative electrode Rn is shifted are secured, the profile correcting unit 120 scales the capacity range of at least one of the adjustment result profiles Rp′, Rn.

According to the example shown in FIG. 18, the profile correcting unit 120 performs an additional adjustment procedure to shrink or expand at least one of the adjusted reference profile of the positive electrode Rp′ and the adjusted reference profile of the negative electrode Rn along the horizontal axis.

Referring to FIG. 19, the profile correcting unit 120 may generate an adjusted reference profile of the positive electrode Rp″ by shrinking or expanding the adjusted reference profile of the positive electrode Rp′ so that the size of the capacity range between the two points pi′, pf′ of the adjusted reference profile of the positive electrode Rp′ matches the size of the capacity range of the measurement full-cell profile M. At this time, any one of the two points pi′, pf′ can be fixed. Accordingly, the capacity difference between the two points pi′, pf″ of the adjusted reference profile of the positive electrode Rp″ can be matched to the capacity range of the measurement full-cell profile M.

In addition, the profile correcting unit 120 may generate an adjusted reference profile of the negative electrode Rn′ by shrinking or expanding the reference profile of the negative electrode Rn so that the size of the capacity range between two points ni, nf of the reference profile of the negative electrode Rn matches the size of the capacity range of the measurement full-cell profile M. At this time, any one of the two points ni, nf can be fixed. Accordingly, the capacity difference between the two points ni, nf′ of the adjusted reference profile of the negative electrode Rn′ can be matched to the capacity range of the measurement full-cell profile M.

In FIG. 19, the adjusted reference profile of the positive electrode Rp″ is the result of shrinkage of the adjusted reference profile of the positive electrode Rp′ shown in FIG. 16, and the adjusted reference profile of the negative electrode Rn′ is the result of expansion of the reference profile of the negative electrode Rn shown in FIG. 18.

The positive electrode participation finalizing point pf″ on the adjusted reference profile of the positive electrode Rp″ corresponds to the positive electrode participation finalizing point pf on the adjusted reference profile of the positive electrode Rp′. The negative electrode participation finalizing point nf′ on the adjusted reference profile of the negative electrode Rn′ corresponds to the negative electrode participation finalizing point nf on the reference profile of the negative electrode Rn.

The capacity difference between the positive electrode participation initiating point pi′ and the positive electrode participation finalizing point pf″ of the adjusted reference profile of the positive electrode Rp″ corresponds to the size of the capacity range of the measurement full-cell profile M. Likewise, the capacity difference between the negative electrode participation initiating point ni and the negative electrode participation finalizing point nf′ of the adjusted reference profile of the negative electrode Rn′ corresponds to the size of the capacity range of the measurement full-cell profile M.

In addition, the capacity range by two points pi′, pf″ of the adjusted reference profile of the positive electrode Rp″ matches the capacity range by two points ni, nf′ of the adjusted reference profile of the negative electrode Rn′. The profile correcting unit 120 may generate the comparison full-cell profile S by subtracting the profile between two points pi, pf of the adjusted reference profile of the positive electrode Rp″ from the profile between two points ni, nf′ of the adjusted reference profile of the negative electrode Rn′.

The profile correcting unit 120 can calculate the error (profile error) between the comparison full-cell profile S and the measurement full-cell profile M. When the error between the comparison full-cell profile S and the measurement full-cell profile M is minimized, the adjusted reference profile of the positive electrode Rp″ corresponding to the comparison full-cell profile S may be determined as the adjusted positive electrode profile, and the adjusted reference profile of the negative electrode Rn′ may be determined as the adjusted negative electrode profile.

The profile correcting unit 120 may map at least two of the adjusted reference profile of the positive electrode Rp “, the adjusted reference profile of the negative electrode Rn′, the positive electrode participation initiating point pi′, the positive electrode participation finalizing point pf”, the negative electrode participation initiating point ni, the negative electrode participation finalizing point nf′, the first scale factor, the second scale factor, the comparison full-cell profile S, and the profile error to each other and record in the storage unit 140. The first scale factor can represent the rate of the capacity difference between two points pi′, pf″ relative to the capacity difference between two points pi0, pf0. The second scale factor may represent the rate of the capacity difference between two points ni, nf′ relative to the capacity difference between two points ni0, nf0.

Here, the profile correcting unit 120 may calculate the positive electrode change rate (ps) of the adjusted reference profile of the positive electrode Rp″ for the reference profile of the positive electrode Rp. Also, the profile correcting unit 120 may calculate the negative electrode change rate (ns) of the adjusted reference profile of the positive electrode Rn′ for the reference profile of the negative electrode Rn. For example, the profile correcting unit 120 may determine the first scale factor as the positive electrode change rate (ps) and determine the second scale factor as the negative electrode change rate (ns).

Meanwhile, as described above, when the positive electrode voltage range of the reference profile of the positive electrode Rp is divided into a plurality of micro voltage sections, the boundary point of two adjacent micro voltage sections among the plurality of micro voltage sections may be set as the positive electrode participation initiating point pi.

For example, if the positive electrode voltage range of the reference profile of the positive electrode Rp is divided into one hundred small voltage ranges, there may be one hundred boundary points that can be set as the positive electrode participation initiating point pi. In addition, if the voltage range equal to or greater than the second setting voltage in the reference profile of the positive electrode Rp is divided into 40 small voltage ranges, there can be 40 boundary points that can be set as the positive electrode participation finalizing point pf. In this case, up to 4000 different comparison full-cell profiles can be generated.

Of course, it will be easy to understand by those skilled in the art that as the size of the micro voltage section decreases, the number of comparison full-cell profiles that can be maximally generated increases, and conversely, as the size of the micro voltage section increases, the number of comparison full-cell profiles that can be maximally generated decreases.

The profile correcting unit 120 may identify the minimum value among the profile errors of the plurality of comparison full-cell profile generated as described above, and then obtain information mapped to the minimum profile error (e.g., at least one of the positive electrode participation initiating point pi, the positive electrode participation finalizing point pf, the negative electrode participation initiating point ni, the negative electrode participation finalizing point nf, the positive electrode change rate (ps), and the negative electrode change rate (ns)) from the storage unit 140.

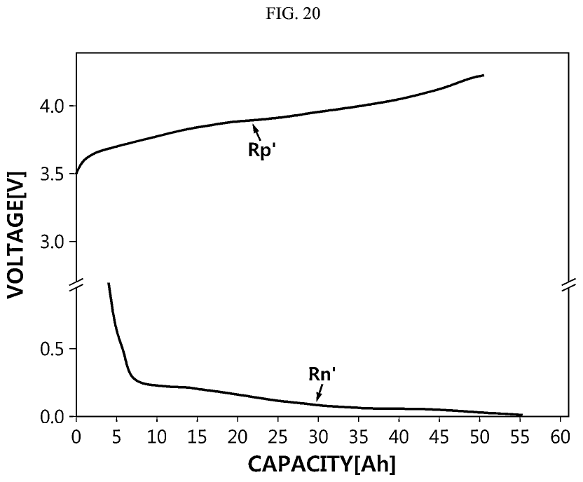

FIGS. 20 to 22 are diagrams referenced to for explaining another example of a procedure for generating a comparison full-cell profile used for comparison with the measurement full-cell profile M according to an embodiment of the present disclosure. For reference, the embodiments shown in FIGS. 20 to 22 are independent from the embodiments shown in FIGS. 17 to 19. Accordingly, terms or symbols commonly used in describing the embodiments shown in FIGS. 17 to 19 and the embodiments shown in FIGS. 20 to 22 should be understood as being limited to each embodiment.

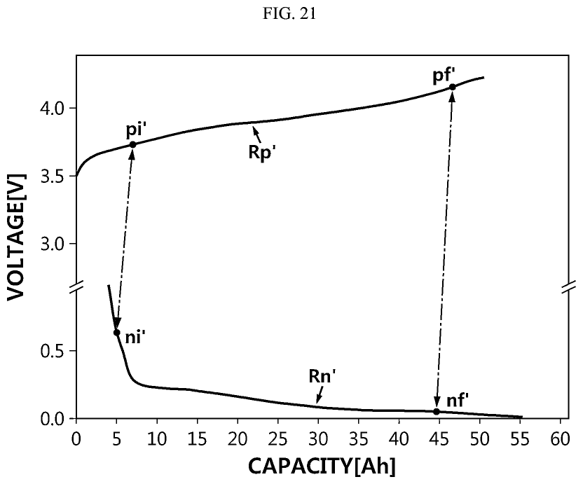

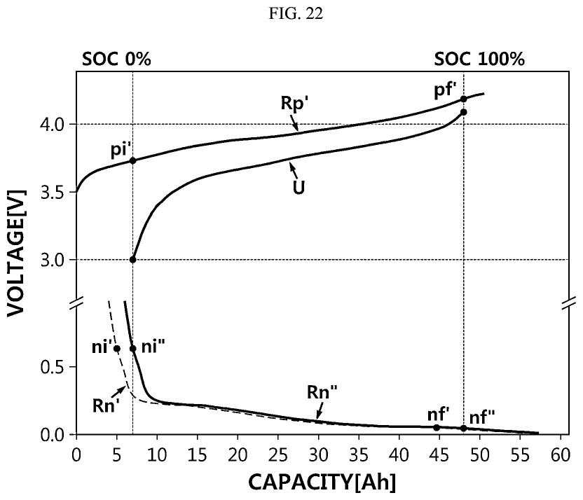

The generation procedure of the comparison full-cell profile to be explained with reference to FIGS. 20 to 22 proceeds in the following order: a fourth routine for performing capacity scaling (see FIG. 20), a fifth routine of setting four points (the positive electrode participation initiating point, the positive electrode participation finalizing point, the negative electrode participation initiating point and the negative electrode participation finalizing point (see FIG. 21), and a sixth routine of performing profile shift (see FIG. 22). That is, the generation procedure of the comparison full-cell profile according to another embodiment of the present disclosure includes the fourth to sixth routine.

Referring to FIG. 20, the reference profile of the positive electrode Rp and the reference profile of the negative electrode Rn are the same as those shown in FIG. 15.

The profile correcting unit 120 generates an adjusted reference profile of the positive electrode Rp′ and an adjusted reference profile of the negative electrode Rn′ by applying the first scale factor and the second scale factor selected from the scaling value range to the reference profile of the positive electrode Rp and the reference profile of the negative electrode Rn, respectively.

The scaling value range may be predetermined or may vary depending on the rate of the size of the capacity range of the measurement full-cell profile M relative to the size of the capacity range of the reference full-cell profile R. As an example, assuming that the first scale factor and the second scale factor can be selected among the values spaced by 0.1% (i.e., 90%, 90.1%, 90.2%, . . . , 98.9%, 99%) in the scaling numerical range (e.g., 90 to 99%), 91 values can be selected as the first scale factor and the second scale factor, respectively. In this case, up to 8,281 adjusted profile pairs can be generated to 91×91=8,281 adjustment levels (combination of first scale factor and second scale factor). The adjusted profile pair refers to a combination of the adjusted reference profile of the positive electrode and the adjusted reference profile of the negative electrode.

FIG. 20 shows an example in which the adjusted reference profile of the positive electrode Rp′ and the adjusted reference profile of the negative electrode Rn′ are the results of applying a first scale factor and a second scale factor less than 100% to the reference profile of the positive electrode Rp and the reference profile of the negative electrode Rn, respectively.

Since the first scale factor and the second scale factor are less than 100%, the adjusted reference profile of the positive electrode Rp′ is the shrinkage of the reference profile of the positive electrode Rp along the horizontal axis, and the adjusted reference profile of the negative electrode Rn′ is also the shrinkage of the reference profile of the negative electrode Rn along the horizontal axis. To facilitate understanding, the example is illustrated in the form where the starting point of each of the positive electrode profile Rp and the reference profile of the negative electrode Rn is fixed and the remaining portions are reduced to the left along the horizontal axis.

Referring to FIG. 21, the profile correcting unit 120 determines the positive electrode participation initiating point pi′, the positive electrode participation finalizing point pf′, the negative electrode participation initiating point ni′ and the negative electrode participation finalizing point nf′ on the adjusted reference profile of the positive electrode Rp′ and the adjusted reference profile of the negative electrode Rn′.

Either the positive electrode participation initiating point pi′ or the negative electrode participation initiating point ni′ may depend on the other. Additionally, either the positive electrode participation finalizing point pf′ or the negative electrode participation finalizing point nf′ may depend on the other. Additionally, either the positive electrode participation initiating point pi′ or the positive electrode participation finalizing point pf′ may be set based on the other.

That is, if any one of the positive electrode participation initiating point pi′, the positive electrode participation finalizing point pf′, the negative electrode participation initiating point ni′, and the negative electrode participation finalizing point nf′ is set, the remaining three points may be set automatically by the first setting voltage, the second setting voltage and/or the size of the capacity range of the measurement full-cell profile M (e.g., charging capacity of SOC 0% to 100%).

As an example, the profile correcting unit 120 may divide the positive electrode voltage range from the start point of the adjusted reference profile of the positive electrode Rp′ to the end point (or second setting voltage) into a plurality of micro voltage section, and then set the boundary point of two adjacent micro voltage sections among the plurality of micro voltage sections as the positive electrode participation initiating point pi′. Next, the profile correcting unit 120 may set the point on the adjusted reference profile of the negative electrode Rn, which is smaller than the positive electrode participation initiating point pi′ by the first setting voltage (e.g., 3 V), as the negative electrode participation initiating point ni′.

As another example, the profile correcting unit 120 may divide the negative electrode voltage range from the start point to the end point of the adjusted reference profile of the negative electrode Rn′ into a plurality of micro voltage sections of a predetermined size, and then set the boundary point of two adjacent voltage sections among the plurality of micro voltage sections as the negative electrode participation initiating point ni′. Next, the profile correcting unit 120 may search for a point, which is greater than the negative electrode participation initiating point ni′ by the first setting voltage, from the reference profile of the positive electrode Rp and set the searched point as the positive electrode participation initiating point pi′.

As another example, the profile correcting unit 120 may divide the voltage range from the second setting voltage to the end point of the adjusted reference profile of the positive electrode Rp′ into a plurality of micro voltage sections of a predetermined size, and then set the boundary point of the two micro voltage sections among the plurality of micro voltage sections as the positive electrode participation finalizing point pf′. Next, the profile correcting unit 120 may search for a point, which is smaller than the positive electrode participation finalizing point pf′ by the second setting voltage (e.g., 4 V), in the adjusted reference profile of the negative electrode Rn′, and set the searched point as the negative electrode participation finalizing point ‘nf’.

As another example, the profile correcting unit 120 may divide the negative electrode voltage range from the start point to the end point of the adjusted reference profile of the negative electrode Rn′ into a plurality of micro voltage sections of a predetermined size, and then set the boundary point of two adjacent micro voltage sections among the plurality of micro voltage sections as the negative electrode participation finalizing point nf′. Next, the profile correcting unit 120 may search for a point, which is greater than the negative electrode participation finalizing point nf′ by the second setting voltage, from the adjusted reference profile of the positive electrode Rp′ and set the searched point as the positive electrode participation finalizing point pf′.

If any one of the positive electrode participation initiating point pi′, the positive electrode participation finalizing point pf′, the negative electrode participation initiating point ni′, and the negative electrode participation finalizing point nf′ is determined, the profile correcting unit 120 may additionally determine the remaining points based on the determined point.

As an example, if the positive electrode participation initiating point pi′ is determined first, the profile correcting unit 120 may set the point on the adjusted reference profile of the positive electrode Rp′, which has a capacity value that is larger than the capacity value of the positive electrode participation initiating point pi′ by the size of the capacity range of the measurement full-cell profile M, as the positive electrode participation finalizing point pf′. Additionally, the profile correcting unit 120 may search for a point, which is lower than the positive electrode participation initiating point pi′ by the first setting voltage, from the adjusted reference profile of the negative electrode Rn′ and set the searched point as the negative electrode participation initiating point ni′. In addition, the profile correcting unit 120 may set a point on the adjusted reference profile of the negative electrode Rn′, which has a capacity value larger than the capacity value of the negative electrode participation initiating point ni′ by the size of the capacity range of the measurement full-cell profile M, as the negative electrode participation finalizing point nf′.

As another example, if the positive electrode participation finalizing point pf′ is determined first, the profile correcting unit 120 may set a point on the adjusted reference profile of the positive electrode Rp′, which has a capacity value smaller than the capacity value of the positive electrode participation finalizing point pf′ by the size of the capacity range of the measurement full-cell profile M, as the positive electrode participation initiating point pi′. Additionally, the profile correcting unit 120 may search for a point, which is lower than the positive electrode participation finalizing point pf′ by the second setting voltage, from the adjusted reference profile of the negative electrode Rn′ and set the searched point as the negative electrode participation finalizing point nf′. In addition, the profile correcting unit 120 may set a point on the adjusted reference profile of the negative electrode Rn′, which has a capacity value smaller than the capacity value of the negative electrode participation finalizing point nf′ by the size of the capacity range of the measurement full-cell profile M, as the negative electrode participation initiating point ni′.

As still another example, if the negative electrode participation initiating point ni′ is determined, the profile correcting unit 120 may set a point on the reference profile of the negative electrode Rn′, which has a capacity value larger than the capacity value of the negative electrode participation initiating point ni′ by the size of the capacity range of the measurement full-cell profile M, set as the negative electrode participation finalizing point nf′. Additionally, the profile correcting unit 120 may search for a point, which is higher than the negative electrode participation initiating point ni′ by the first setting voltage, from the adjusted reference profile of the positive electrode Rp′ and set the searched point as the positive electrode participation initiating point pi′. In addition, the profile correcting unit 120 may set a point on the adjusted reference profile of the positive electrode Rp′, which has a capacity value greater than the capacity value of the positive electrode participation initiating point pi′ by the size of the capacity range of the measurement full-cell profile M, as the positive electrode participation finalizing point pf′.

As still another example, if the negative electrode participation finalizing point nf′ is determined, the profile correcting unit 120 may set a point on the reference profile of the negative electrode Rn′, which has a capacity value smaller than the capacity value of the negative electrode participation finalizing point nf′ by the size of the capacity range of the measurement full-cell profile M, as the negative electrode participation initiating point ni′. Additionally, the profile correcting unit 120 may search for a point, which is higher than the negative electrode participation finalizing point nf′ by the second setting voltage, from the adjusted reference profile of the positive electrode Rp′ and set the searched point as the positive electrode participation finalizing point pf′. In addition, the profile correcting unit 120 may set a point on the adjusted reference profile of the positive electrode Rp′, which has a capacity value smaller than the capacity value of the positive electrode participation finalizing point pf′ by the size of the capacity range of the measurement full-cell profile M, as the positive electrode participation initiating point pi′.

If the determination of the positive electrode participation initiating point pi′, the positive electrode participation finalizing point pf′, the negative electrode participation initiating point ni′ and the negative electrode participation finalizing point nf′ is completed based on the pair of first scale factor and second scale factor, the profile correcting unit 120 may shift at least one of the adjusted reference profile of the positive electrode Rp′ and the adjusted reference profile of the negative electrode Rn′ along the horizontal axis so that the capacity values of the positive electrode participation initiating point pi′ and the negative electrode participation initiating point ni′ match or the capacity values of the positive electrode participation finalizing point pf′ and the negative electrode participation finalizing point nf match.

The adjusted reference profile of the negative electrode Rn″ shown in FIG. 22 is obtained by shifting only the adjusted reference profile of the negative electrode Rn′ shown in FIG. 21 to the right. Accordingly, the capacity values of the positive electrode participation initiating point pi′ and the negative electrode participation initiating point ni″ do not match each other. In this regard, since the capacity difference between the positive electrode participation initiating point pi′ and the positive electrode participation finalizing point pf′ is the same as the capacity difference between the negative electrode participation initiating point ni′ and the negative electrode participation finalizing point nf′, if the capacity values of the positive electrode participation initiating point pi′ and the negative electrode participation initiating point ni″ match each other, the capacity values of the positive electrode participation finalizing point pf′ and the negative electrode participation finalizing point nf″ also match each other.

Referring to FIG. 22, the profile correcting unit 120 may generate the comparison full-cell profile U by subtracting a partial profile between two points pi′, pf′ of the adjusted reference profile of the positive electrode Rp′ from the partial profile between into two points ni″, nf″ of the adjusted reference profile of the negative electrode Rn″.

The profile correcting unit 120 may calculate the error (profile error) between the comparison full-cell profile U and the measurement full-cell profile M. When the error between the comparison full-cell profile U and the measurement full-cell profile M is minimized, the adjusted reference profile of the positive electrode Rp′ corresponding to the comparison full-cell profile U may be determined as the adjusted positive electrode profile, and the adjusted reference profile of the negative electrode Rn″ may be determined as the adjusted negative electrode profile.

The profile correcting unit 120 may map at least two of the adjusted reference profile of the positive electrode Rp′, the adjusted reference profile of the negative electrode Rn″, the positive electrode participation initiating point pi′, the positive electrode participation finalizing point pf′, the negative electrode participation initiating point ni″, the negative electrode participation finalizing point nf″, the positive electrode change rate ps, the negative electrode change rate ns, the comparison full-cell profile U, and the profile error with each other and record in the storage unit 140.

Here, the profile correcting unit 120 may calculate the positive electrode change rate ps of the adjusted reference profile of the positive electrode Rp′ for the reference profile of the positive electrode Rp. Also, the profile correcting unit 120 may calculate the negative electrode change rate ns of the adjusted reference profile of the negative electrode Rn″ for the reference profile of the negative electrode Rn. For example, the profile correcting unit 120 may determine the first scale factor as the positive electrode change rate ps and determine the second scale factor as the negative electrode change rate ns.

As described above, the profile correcting unit 120 may generate a comparison full-cell profile corresponding to each pair of first scale factor and second scale factor selected from the scaling value range. Since the pair of first scale factor and second scale factor is plural, it is obvious that the comparison full-cell profile will also be generated in plural. The profile correcting unit 120 may identify the minimum value among the profile errors of the plurality of comparison full-cell profiles and then obtain information mapped to the minimum profile error from the storage unit 140.

The apparatus 100 for diagnosing a battery according to the present disclosure may be connected to a display device (not shown) and output information on a battery diagnosed as being in an abnormal state. Because of this, the information about the battery diagnosed as being in an abnormal state may be displayed on the display device.

The apparatus 100 for diagnosing a battery according to the present disclosure may be connected to an alarm device (not shown) and output information on a battery diagnosed as being in an abnormal state to operate the alarm device.

The apparatus 100 for diagnosing a battery according to the present disclosure can be applied to the BMS. In other words, the BMS according to the present disclosure may include the above-described apparatus 100 for diagnosing a battery. In this configuration, at least some of the components of the apparatus 100 for diagnosing a battery may be implemented by supplementing or adding functions of components included in a conventional BMS. For example, the profile obtaining unit 110, the profile correcting unit 120, the control unit 130 and the storage unit 140 of the apparatus 100 for diagnosing a battery may be implemented as components of a BMS.

Additionally, the apparatus 100 for diagnosing a battery according to the present disclosure may be provided in the battery pack. That is, the battery pack according to the present disclosure may include the above-described apparatus 100 for diagnosing a battery and at least one battery cell. Additionally, the battery pack may further include electrical components (relays, fuses, etc.) and a case.

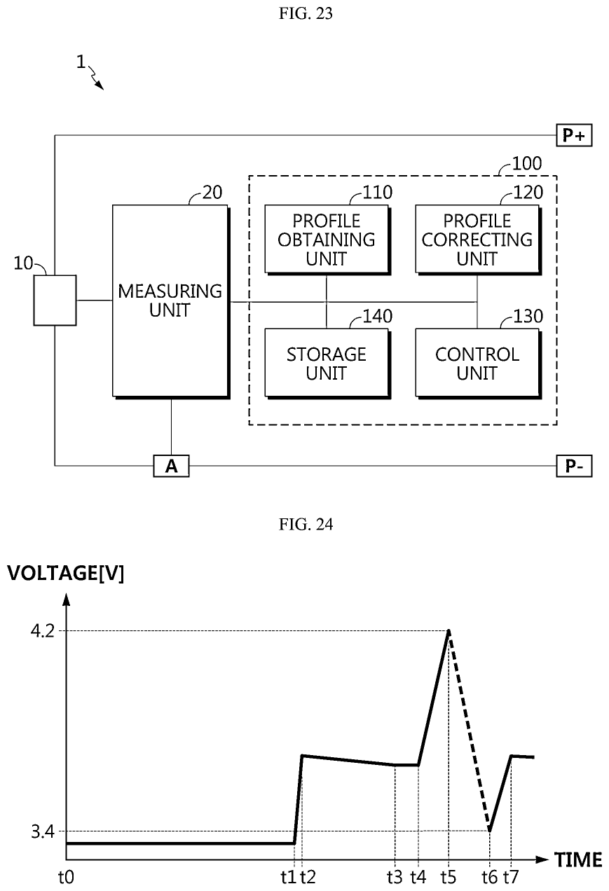

FIG. 23 is a diagram showing an exemplary configuration of the battery pack 1 including according to another embodiment of the present disclosure.

The positive electrode terminal of the battery 10 may be connected to the positive electrode terminal P+ of the battery pack 1, and the negative electrode terminal of the battery 10 may be connected to the negative electrode terminal P—of the battery pack 1.

The measuring unit 20 can be connected to the positive electrode terminal and the negative electrode terminal of the battery 10. Additionally, the measuring unit 20 can measure the voltage of the battery 10 by measuring the positive electrode potential and the negative electrode potential of the battery 10 and calculating the difference between the positive electrode potential and the negative electrode potential.

In addition, the measuring unit 20 can be connected to a current measurement unit A. For example, the current measurement unit A may be an ammeter or shunt resistor that can measure the charging current and discharging current of the battery 10. The measuring unit 20 can calculate the charging amount by measuring the charging current of the battery 10 using the current measurement unit A. Additionally, the measuring unit 20 can calculate the discharge amount by measuring the discharge current of the battery 10 through the third sensing line SL3.

For example, the information about the voltage and capacity of the battery 10 measured by the measuring unit 20 may be transmitted to the profile obtaining unit 110. Additionally, the profile obtaining unit 110 can directly generate a battery profile BP based on the received information about the voltage and capacity.

As another example, the information about the voltage and capacity of the battery 10 measured by the measuring unit 20 may be stored in the storage unit 140. When the charging or discharging of the battery 10 is completed, the profile obtaining unit 110 may access the storage unit 140 to obtain the battery profile BP.

As still another example, the measuring unit 20 may directly generate a battery profile BP based on the measured information about the voltage and capacity of the battery 10. In this case, the generated battery profile BP may be transmitted to the profile obtaining unit 110 and also be stored in the storage unit 140.

A charge/discharge device or load can be connected to the positive electrode terminal P+ and the negative electrode terminal P—of the battery pack 1.

FIG. 24 is a diagram for explaining the process of manufacturing a battery cell by a battery manufacturing system according to still another embodiment of the present disclosure. Specifically, FIG. 24 is a diagram schematically showing the process of activating a manufactured battery cell over time.

Referring to FIG. 24, the aging process proceeds in the first step from the to time point to the t1 time point. Here, the aging process refers to a process of leaving the battery cell under specific conditions. In the first step, the electrolyte may be impregnated. Primary charging proceeds in the second step from the t1 time point to the t2 time point. In the second step, a film layer (SEI, solid electrolyte interphase) can be formed on the negative electrode.

A high temperature aging process proceeds in the third step from the t2 time point to the t3 time point. For example, in the third step, aging occurs under high temperature conditions of 60° C., and the film layer formed in the second step can be stabilized. The degassing process proceeds in the fourth step from the t3 time point to the t4 time point. In the fourth step, the gas contained inside the battery cell can be removed.

The process of charging the battery cell proceeds in the fifth step from the t4 time point to the t5 time point. The battery cell discharge process proceeds in the sixth step from the t5 time point to the t6 time point. Here, the fifth step and the sixth step can be combined and referred to as the battery cell capacity inspection process. Generally, the sixth step is a step of detecting a defect in the battery cell while discharging a fully charged battery cell, and is a process step of discharging the battery cell at a discharge C-rate determined in consideration of the inspection time and inspection accuracy. For example, in the sixth step, the battery cell is discharged at 0.3 C, and the battery profile BP for capacity and voltage can be obtained during the discharge process. Also, based on the obtained battery profile BP, it may be detected whether the battery cell is defective.

In the seventh step from the t6 time point to the t7 time point, the shipping and charging process to ship the battery cell is carried out.

The apparatus 100 for diagnosing a battery according to an embodiment of the present disclosure can obtain a battery profile BP generated in the discharge process of the sixth step. Also, by removing the overpotential included in the battery profile BP using the overpotential profile OP corresponding to the target C-rate set in the discharge process, the corrected profile CP for the plurality of battery cells can be obtained. Also, the apparatus 100 for diagnosing a battery can diagnose the state of the plurality of battery cells based on the plurality of corrected profiles CP. In other words, the apparatus 100 for diagnosing a battery can be used in the battery cell activation process step to quickly and accurately diagnose defects in the manufactured battery cell. In particular, the apparatus 100 for diagnosing a battery has an advantage of detecting defective battery cells more accurately because it diagnoses the state of the battery cell after removing the overpotential that may be included in the battery profile BP obtained in the capacity inspection process.

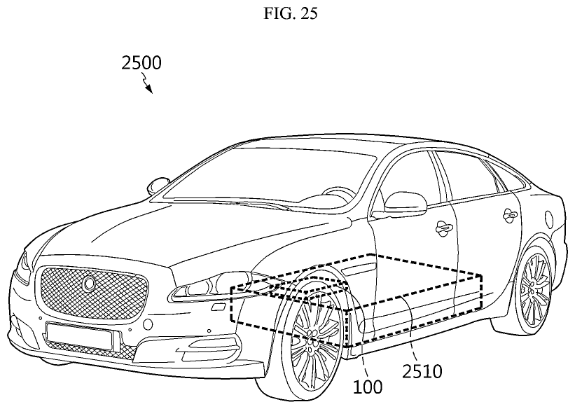

FIG. 25 is a diagram schematically showing an exemplary configuration of a vehicle according to still another embodiment of the present disclosure.

Referring to FIG. 25, the battery pack 2510 according to an embodiment of the present disclosure may be included in a vehicle 2500 such as an electric vehicle (EV) or a hybrid vehicle (HV). In addition, the battery pack 2510 may drive the vehicle 2500 by supplying power to a motor through an inverter included in the vehicle 2500. Here, the battery pack 2510 may include the apparatus 100 for diagnosing a battery. That is, the vehicle 2500 may include the apparatus 100 for diagnosing a battery. In this case, the apparatus 100 for diagnosing a battery may be an on-board diagnostic device included in the vehicle 2500.

Computer-readable media having stored thereon instructions configured to cause one or more computers to perform any of the methods described herein are also described. A computer readable medium may include volatile or nonvolatile, removable or nonremovable media implemented in any method or technology capable of storing information, such as computer readable instructions, data structures, program modules, or other data. In general, functionality of computing devices described herein may be implemented in computing logic embodied in hardware or software instructions, which can be written in a programming language, such as C, C++, COBOL, JAVA™, PHP, Perl, Python, Ruby, HTML, CSS, JavaScript, VBScript, ASPX, Microsoft.NET™ languages such as C#, and/or the like. Computing logic may be compiled into executable programs or written in interpreted programming languages. Generally, functionality described herein can be implemented as logic modules that can be duplicated to provide greater processing capability, merged with other modules, or divided into sub modules. The computing logic can be stored in any type of computer readable medium (e.g., a non-transitory medium such as a memory or storage medium) or computer storage device and be stored on and executed by one or more general purpose or special purpose processors, thus creating a special purpose computing device configured to provide functionality described herein. The applications and the functionalities disclosed in the foregoing and following embodiments may be achieved by programming the apparatus 100 or pack 1 in accordance with the description provided in connection with, for example, FIGS. 1-25. That is, the apparatus 100 or pack 1 1 in the foregoing and following embodiments may utilize, for example, computer-readable media having stored thereon instructions configured to cause one or more computers or processors to perform any of the methods described herein.

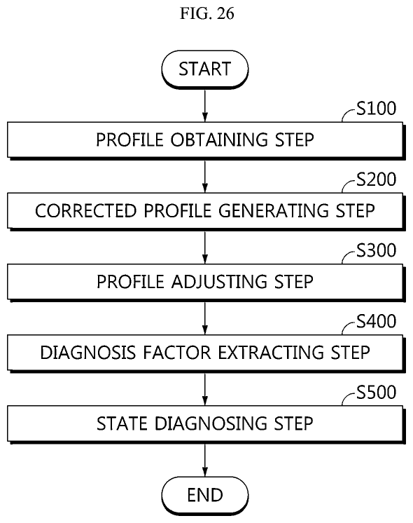

FIG. 26 is a diagram schematically showing a method for executing functions and methods for diagnosing a battery based on apparatus 100 or pack 1 disclosed in connection with FIGS. 1-25, according aspects of the present disclosure.

The method for diagnosing a battery may include a profile obtaining step (S100), a corrected profile generating step (S200), a profile adjusting step (S300), a diagnostic factor extracting step (S400), and a state diagnosing step (S500).

Preferably, each step of the method for diagnosing a battery may be performed by the apparatus 100 for diagnosing a battery. Hereinafter, for convenience of explanation, content that overlaps with the content described above will be omitted or briefly described.

The profile obtaining step (S100) may be a step of obtaining each of a plurality of battery profiles BP indicating the correspondence relationship between voltage and capacity of each of the plurality of batteries, and may be performed by the profile obtaining unit 110. For example, the profile obtaining unit 110 may directly receive the battery profile BP from the outside. That is, the profile obtaining unit 110 may obtain the battery profile BP by receiving the battery profile BP by being connected to the outside by wire(s) and/or wirelessly.

As another example, the profile obtaining unit 110 may receive battery information about the voltage (V) and capacity (Q) of the battery. Additionally, the profile obtaining unit 110 may generate a battery profile BP based on the received battery information. That is, the profile obtaining unit 110 may obtain the battery profile BP by directly generating the battery profile BP based on the battery information.

In one embodiment, the profile obtaining unit 110 may obtain a first profile based on a voltage value of the battery and a capacity value of the battery.

The corrected profile generating step (S200) is a step for generating a plurality of corrected profiles CP by correcting the plurality of battery profiles BP based on a preset overpotential profile OP, and may be performed by the profile correcting unit 120.

Specifically, the profile correcting unit 120 may remove the overpotential profile OP from the battery profile BP. For example, the profile correcting unit 120 may calculate the difference between the voltage of the battery profile BP and the overpotential of the overpotential profile OP for the same capacity. The profile correcting unit 120 may generate a corrected profile CP by calculating the difference between the voltage of the battery profile BP and the overpotential of the overpotential profile OP at the total capacity.

In one embodiment, the profile correcting unit 120 may generate a second profile based on an overpotential profile associated with the first profile, and generate a third profile based on a first reference profile and the second profile. For example, the third profile may be an adjusted positive electrode profile, and the first reference profile may be a positive electrode reference profile. In another embodiment, the profile correcting unit is further configured to generate a fourth profile based on a second reference profile and the second profile.

In one embodiment, the overpotential profile may be generated based on a fifth profile and a sixth profile, the fifth profile being based on a reference battery and the sixth profile being based on a target battery. The fifth profile may be generated based on a first C-rate value and the sixth battery profile may be generated based on a second C-rate value. For example, the first C-rate value may be used for charging or discharge the reference battery, and the second C-rate value may be used for charging or discharging the target battery. In one embodiment, the overpotential profile may be generated further based on a difference between a voltage value of the fifth profile and a voltage value of the sixth profile.

In one embodiment, the profile correcting unit 120 may be further configured to generate the second profile by calculating a difference between a voltage value of the first profile and a voltage value of the overpotential profile.

In one embodiment, the profile obtaining unit 110 may be configured to obtain a plurality of overpotential profiles corresponding to a plurality of C-rates, and the profile correcting unit 120 is further configured to select at least one of the plurality of overpotential profiles corresponding to the second C-rate. According to one embodiment, the profile correcting unit 120 may be further configured to generate the second profile based on the at least one of the plurality of overpotential profiles.

In one embodiment, the profile correcting unit 120 may be configured to generate a comparison profile based on the first reference profile and the second reference profile, and generate the third profile and the fourth profile by adjusting the first reference profile and the second reference profile. The first reference profile and the second reference profile may be adjusted to generate the comparison profile that corresponds with the second profile.

The profile adjusting step (S300) is a step of generating an adjusted positive electrode profile and an adjusted negative electrode profile corresponding to each battery by adjusting a preset reference profile of the positive electrode and a preset reference profile of the negative electrode to correspond to each of the plurality of corrected profiles CP, and may be performed by the profile correcting unit 120.

For example, the profile correcting unit 120 may generate a plurality of comparison full-cell profiles by shifting the reference profile of the positive electrode and the reference profile of the negative electrode or scaling the capacity thereof, and specify a comparison full-cell profile having a minimum error with the corrected profile CP among the plurality of comparison full-cell profiles. Also, an adjusted positive electrode profile and an adjusted negative electrode profile corresponding to the specified comparison full-cell profile may be determined.

The diagnostic factor extracting step (S400) is a step of extracting a diagnostic factor for each battery from at least one of the adjusted positive electrode profile and the adjusted negative electrode profile, and may be performed by the control unit 130.

Specifically, the control unit 130 may extract a diagnostic factor related to the positive electrode from the adjusted positive electrode profile. Additionally, the control unit 130 may extract a diagnostic factor related to the negative electrode from the adjusted negative electrode profile. Additionally, the control unit 130 may extract a diagnostic factor related to the positive and negative electrodes in consideration of both the diagnostic factor related to the positive electrode and the diagnostic factor related to the negative electrode.

For example, the positive electrode factor may include at least one of a positive electrode start potential, a positive electrode end potential, a positive electrode change rate, and a positive electrode loading amount of the battery based on the adjusted positive electrode profile. The negative electrode factor may include at least one of a negative electrode start potential, a negative electrode end potential, a negative electrode change rate, and a negative electrode loading amount of the battery based on the adjusted negative electrode profile. The positive and negative electrode factor may include an NP ratio based on a positive electrode loading amount and a negative electrode loading amount.

In one embodiment, the control unit 130 may generate one or more diagnostic factors based on the third profile. In one embodiment, the control unit 130 may be configured to generate the one or more diagnostic factors based on the third profile or the fourth profile. In one embodiment, the control unit 130 may be configured to determine at least one of a first factor based on the third profile, a second factor based on the fourth profile, or a third factor based on the first factor and the second factor. For example, the first factor may be based on at least one of a first electrode start potential, a first electrode end potential, a first electrode change rate, or a first electrode loading amount of the battery, and the at least one of the first electrode start potential, the first electrode end potential, the first electrode change rate, or the first electrode loading amount of the battery may be based on the third profile. The second electrode factor may be based on at least one of a second electrode start potential, a second electrode end potential, a second electrode change rate, or a second electrode loading amount of the battery, and the at least one of the second electrode start potential, the second electrode end potential, the second electrode change rate, or the second electrode loading amount of the battery may be based on fourth profile. The third electrode factor may be based on a ratio between the first electrode loading amount and the second electrode loading amount.

The state diagnosing step (S500) is a step of diagnosing the state of the plurality of batteries based on the extracted plurality of diagnostic factors, and may be performed by the control unit 130.

For example, the control unit 130 may be configured to select a diagnostic factor that is outside the threshold range TH among the plurality of diagnostic factors in consideration of the distribution of the plurality of diagnostic factors, and diagnose the state of the battery corresponding to the selected diagnostic factor as an abnormal state. Conversely, the control unit 130 may be configured to select a diagnostic factor included in the threshold range TH among the plurality of diagnostic factors and diagnose the state of the battery corresponding to the selected diagnostic factor as a normal state.

In one embodiment, the control unit 130 may be configured to determine a state of the battery based on the one or more diagnostic factors. In one embodiment, the control unit 130 may be configured to select at least one of the one or more diagnostic factors, determine distribution data based on the plurality of diagnosis factors, and determine the state of the battery based on the distribution data, wherein the state of the battery is a first state or a second state. For example, the first state may be outside of a threshold range of the distribution data, such as an abnormal state of the battery.

The steps of the methods described in the foregoing embodiments improves the conventional battery diagnosing technology by providing, among other things, the apparatus 100 for diagnosing a battery that can be utilized in various applications, for example, but not limited to, battery pack, electric vehicle, etc. That is, the apparatus 100, pack 1, processes, and methods of the foregoing embodiments are directed to an improvement in the field of battery technology and are practically applicable to the field of battery diagnosis by utilizing the apparatus 100 or pack 1, as well the methods, processes, and functionality disclosed in connection with FIGS. 1-26 of the present disclosure. Accordingly, the apparatus 100, pack 1, as well as the individual or combination of multiples steps of the methods, process, and functionality of the present disclosure significantly improve diagnosing the state of battery and/or battery electrodes by deriving diagnostic factors from battery profiles.

The embodiments of the present disclosure described above may not be implemented only through an apparatus and a method, but may be implemented through a program that realizes a function corresponding to the configuration of the embodiments of the present disclosure or a recording medium on which the program is recorded. The program or recording medium may be easily implemented by those skilled in the art from the above description of the embodiments.

The present disclosure has been described in detail. However, it should be understood that the detailed description and specific examples, while indicating preferred embodiments of the disclosure, are given by way of illustration only, since various changes and modifications within the scope of the disclosure will become apparent to those skilled in the art from this detailed description.

Additionally, many substitutions, modifications and changes may be made to the present disclosure described hereinabove by those skilled in the art without departing from the technical aspects of the present disclosure, and the present disclosure is not limited to the above-described embodiments and the accompanying drawings, and each embodiment may be selectively combined in part or in whole to allow various modifications.

### Explanation of Reference Signs

1: battery pack
10: battery
20: measuring unit
100: apparatus for diagnosing a battery
110: profile obtaining unit
120: profile correcting unit
130: control unit
140: storage unit
2500: vehicle
2510: battery pack

What is claimed is:

1. An apparatus for diagnosing a battery, comprising:
a profile obtaining unit configured to obtain a first profile, the first profile being based on a voltage value of the battery and a capacity value of the battery;
a profile correcting unit configured to:
generate a second profile based on an overpotential profile associated with the first profile, and
generate a third profile based on a first reference profile and the second profile; and
a control unit configured to:
generate one or more diagnostic factors based on the third profile, and determine a state of the battery based on the one or more diagnostic factors.

2. The apparatus according to claim 1, wherein the profile correcting unit is further configured to generate a fourth profile based on a second reference profile and the second profile, and
wherein the control unit is further configured to generate the one or more diagnostic factors based on the third profile or the fourth profile.

3. The apparatus according to claim 1, wherein the third profile is an adjusted positive electrode profile, and
wherein the first reference profile is a positive electrode reference profile.

4. The apparatus according to claim 1,
wherein the overpotential profile is generated based on a fifth profile and a sixth profile, the fifth profile being based on a reference battery and the sixth profile being based on a target battery,
wherein the fifth profile is generated based on a first C-rate value and the sixth battery profile is generated based on a second C-rate value.

5. The apparatus according to claim 1, wherein the first C-rate value is used for charging or discharge the reference battery, and
wherein the second C-rate value is used for charging or discharging the target battery.

6. The apparatus according to claim 4, wherein the overpotential profile is generated further based on a difference between a voltage value of the fifth profile and a voltage value of the sixth profile.

7. The apparatus according to claim 1,
wherein the profile correcting unit is further configured to generate the second profile by calculating a difference between a voltage value of the first profiles and a voltage value of the overpotential profile.

8. The apparatus according to claim 4,
wherein a plurality of overpotential profiles corresponding to a plurality of C-rates is obtained by the profile obtaining unit, and
wherein the profile correcting unit is further configured to select at least one of the plurality of overpotential profiles corresponding to the second C-rate and
wherein the profile correcting unit is further configured to generate second profiles based on the at least one of the plurality of overpotential profiles.

9. The apparatus according to claim 1,
wherein the control unit is further configured to:
select at least one of the one or more diagnostic factors;
determine distribution data based on plurality of diagnostic factors; and
determine the state of the battery based on the distribution data,
wherein the state of the battery is a first state or a second state.

10. The apparatus according to claim 9, wherein the first state is outside of a threshold range of the distribution data, and
wherein the first state is an abnormal state of the battery.

11. The apparatus for diagnosing a battery according to claim 2,
wherein the control unit is further configured to determine at least one of a first factor based on the third profile, a second factor based on the fourth profile, or a third factor based on the first factor and the second factor.

12. The apparatus according to claim 11,
wherein the first factor is based on at least one of a first electrode start potential, a first electrode end potential, a first electrode change rate, or a first electrode loading amount of the battery,
wherein the at least one of the first electrode start potential, the first electrode end potential, the first electrode change rate, or the first electrode loading amount of the battery is based on the third profile,
wherein the second electrode factor is based on at least one of a second electrode start potential, a second electrode end potential, a second electrode change rate, or a second electrode loading amount of the battery,
wherein the at least one of the second electrode start potential, the second electrode end potential, the second electrode change rate, or the second electrode loading amount of the battery is based on the fourth profile, and
wherein the third electrode factor is based on a ratio between the first electrode loading amount and the second electrode loading amount.

13. The apparatus according to claim 2,
wherein the profile correcting unit is further configured to:
generate a comparison profile based on the first reference profile and the second reference profile; and
generate the third profile and the fourth profile by adjusting the first reference profile and the second reference profile,
wherein the first reference profile and the second reference profile are adjusted to generate the comparison profile that corresponds with the second profile.

14. A battery pack, comprising the apparatus for diagnosing the battery according to claim 1.

15. A battery manufacturing system, comprising the apparatus for diagnosing the battery according to claim 1.

16. A vehicle, comprising the apparatus for diagnosing the battery according to claim 1.

17. A method for diagnosing a battery, comprising:
obtaining a first profile, the first profile being based on a voltage value of the battery and a capacity value of the battery;
generating a second profile based on an overpotential profile associated with the first profile;
generating a third profile based on a first reference profile and the second profile;
generating one or more diagnostic factors based on the third profile; and
determining a state of the battery based on the one or more diagnostic factors.

18. The method according to claim 17, further comprising generating a fourth profile based on a second reference profile and the second profile, and
generating the diagnostic factor based on the third profile or the fourth profile.

19. The method according to claim 17, wherein the third profile is a positive electrode profile, and
wherein the first reference profile is a positive electrode reference profile.

20. The apparatus according to claim 17, further comprising:
generating the overpotential profile based on a fifth profile and a sixth profile, the fifth profile and the sixth profile being based on a reference battery;
generating the fifth profile based on a first C-rate value; and
generating the sixth battery profile based on a second C-rate value.
